(19) United States
(12) Patent Application Publication
(10) Pub. No.: US 2026/0239740 A1
(43) Pub. Date: Aug. 13, 2026

(54) SEMICONDUCTOR DEVICE AND METHODS OF FORMATION

(71) Applicant: Taiwan Semiconductor Manufacturing Co., Ltd., Hsinchu (TW)

(72) Inventors: Paulina RINCON, Hsinchu (TW); Gerben DOORNBOS, Hsinchu (TW); Georgios VELLIANITIS, Hsinchu (TW); Viraj Nilesh MADHIWALA, Hsinchu (TW); Marcus Johannes Henricus VAN DAL, Hsinchu (TW)

(73) Assignee: Taiwan Semiconductor Manufacturing Co., Ltd., Hsinchu (TW)

(21) Appl. No.: 19/231,251

(22) Filed: Jun. 6, 2025

Related U.S. Application Data
(60) Provisional application No. 63/757,675, filed on Feb. 12, 2025.

(51) Int. Cl. H10D 86/00; H01L 23/00; H10D 30/01; H10D 30/62; H10D 62/13; H10D 86/01

(52) U.S. Cl. CPC H10D 86/215; H10D 30/024; H10D 30/62; H10D 62/151; H10D 86/011; H10W 90/734

(57) ABSTRACT

A fin-based transistor includes a gate structure that is vertically-arranged with source/drain structures of the fin-based transistor. The gate structure may wrap around the top and sides of a fin structure of the fin-based transistor, and source/drain structures of the fin-based transistor are located on a bottom of the fin structure. Source/drain contacts of the fin-based transistor are located on the source/drain structures over the bottom of the fin structure. This enables the gate structure and the source/drain contacts to be located on vertically opposing sides of the fin structure, thereby enabling gate spacers to be omitted from the fin-based transistor.

### BACKGROUND

Fin-based transistors, such as fin field effect transistors (finFETs) and nanostructure transistors (e.g., nanowire transistors, nanosheet transistors, gate-all-around (GAA) transistors, multi-bridge channel transistors, nanoribbon transistors), are three-dimensional structures that include a channel region in a fin (or a portion thereof) that extends above a semiconductor substrate as a three-dimensional structure. A gate structure, configured to control a flow of charge carriers within the channel region, wraps around the fin of semiconductor material. As an example, in a finFET, the gate structure wraps around three sides of the fin (and thus the channel region), thereby enabling increased control over the channel region (and therefore switching of the finFET). As another example, in a nanostructure transistor, the gate structure wraps around a plurality of channel regions in a fin structure such that the gate structure surrounds each of the plurality of channel regions. Source/drain structures (e.g., epitaxial regions) are located on opposing sides of the gate structure.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1-7K illustrate example implementations of forming a fin-based transistor structure according to example embodiments herein.

FIGS. 8A-8L illustrate of example implementations of forming a fin-based transistor structure according to other example embodiments herein.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In some cases, a fin-based transistor may include gate spacers between a gate structure of the fin-based transistor and the source/drain contacts of the fin-based transistor. The gate spacers are included to provide electrical isolation and/or to facilitate patterning of various layers and/or structures of the fin-based transistor. However, the gate spacers can be a source of parasitic capacitance between the gate structure and the source/drain contacts, leading to reduced switching speeds (e.g., because of an increased resistance-capacitance (RC) time constant) for the fin-based transistor. Moreover, the gate spacers account for approximately 25% or greater of the overall size of the fin-based transistor. As a result, the gate spacers pose a challenge to reducing the overall size of the fin-based transistor as semiconductor processing nodes advance.

In some implementations described herein, a fin-based transistor includes a gate structure that is vertically-arranged with source/drain structures of the fin-based transistor. The gate structure may wrap around the top and sides of a fin structure of the fin-based transistor, and source/drain structures of the fin-based transistor may be located on a bottom of the fin structure. Source/drain contacts of the fin-based transistor are located on the source/drain structures over the bottom of the fin structure. This enables the gate structure and the source/drain contacts to be located on vertically opposing sides of the fin structure, thereby enabling gate spacers to be omitted from the fin-based transistor. In this way, parasitic capacitance in the fin-based transistor is reduced, and further size reductions for the fin-based transistor can be realized. Additionally and/or alternatively, vertically stacking the gate structure and the source/drain structures of the fin-based transistor enable front-side and back-side connections to be formed for the fin-based transistor. This enables multiple layers of fin-based transistors to be vertically stacked and interconnected to realize complementary metal-oxide-semiconductor (CMOS) logic circuitry and/or to achieve greater fin-based transistor density in a semiconductor device.

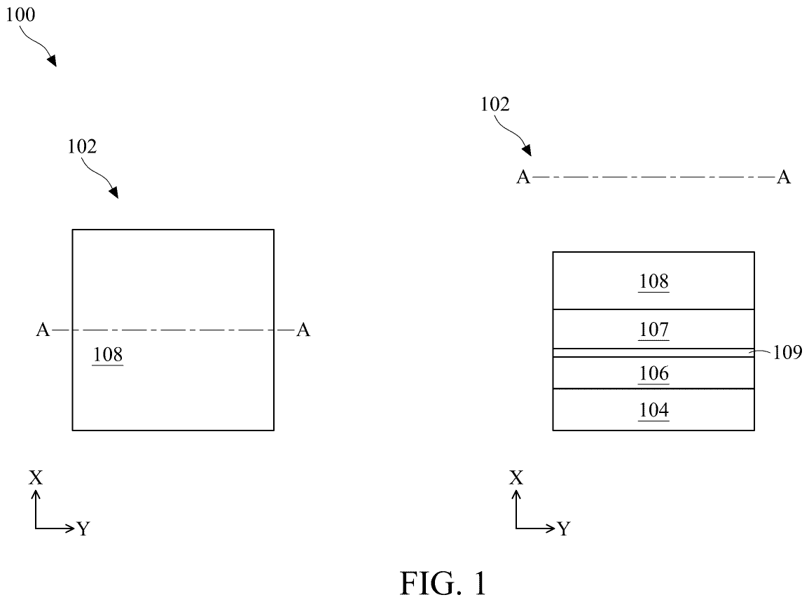

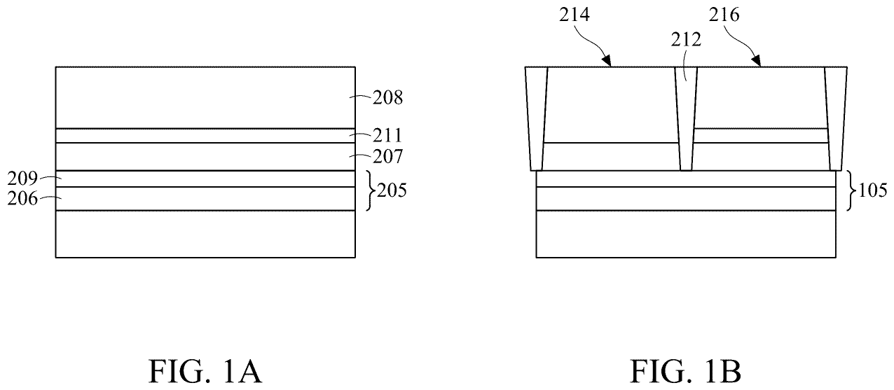

FIGS. 1-7K illustrate example implementations of forming a fin-based transistor structure described herein.

In an example implementation shown in FIG. 1, forming semiconductor layers of a semiconductor wafer 102 (a portion of a wafer is shown for illustrative purposes) may include providing a semiconductor substrate 104, forming an etch stop layer (e.g., a semiconductor etch stop layer) 106 over and/or on the semiconductor substrate 104, and forming a semiconductor layer 108 over and/or on the etch stop layer 106.

The semiconductor substrate 104 may be provided as a semiconductor die, a semiconductor wafer, and/or another type of semiconductor workpiece. The semiconductor substrate 104, the etch stop layer 106, and the semiconductor layer 108 may each include a semiconductor material such as silicon (Si), doped silicon, germanium (Ge), silicon germanium (SiGe), and/or another type of semiconductor material. In some implementations, the semiconductor substrate 104 and the semiconductor layer 108 include a first semiconductor material such as silicon, and the etch stop layer 106 includes a second semiconductor material such as silicon germanium. This enables the etch stop layer 106 to function as an etch stop when etching the semiconductor layer 108, or removing the semiconductor substrate 104.

In some implementations, a sacrificial layer 107 is provided between the semiconductor layer 108 and the etch stop layer 106. In some implementations, the sacrificial layer 107 includes etch selectivity with respect to the semiconductor layer 108 and with respect to the etch stop layer 106. For example, in a case the semiconductor layer 108 is silicon, the sacrificial layer 107 is silicon germanium that has a different Ge concentration from that of the etch stop layer 106. For example, the sacrificial layer 107 of SiGe includes a percentage of Ge in a range of 15%-25% by atomic volume. In some implementations, the sacrificial layer 107 of SiGe includes 25% of Ge by atomic volume. For example, the etch stop layer 106 of SiGe includes a percentage of Ge in a range of 34%-42% by atomic volume. In some implementations, the etch stop layer 106 of SiGe includes 38% of Ge by atomic volume. However, other values and ranges are within the scope of the present disclosure.

In some implementations, the semiconductor layer 108 of Si includes a thickness in a range of 50-70 nm, inclusive. For example, the semiconductor layer 108 of Si includes a thickness of 60 nm. The sacrificial layer 107 of SiGe includes a thickness in a range of 10 nm-20 nm. For example, the sacrificial layer 107 of SiGe includes a thickness of 15 nm. The etch stop layer 106 of SiGe includes a thickness in a range of 10 nm-50 nm. For example, the etch stop layer 106 of SiGe includes a thickness of 20 nm. However, other values and ranges are within the scope of the present disclosure

In some implementations, a Si layer 109 is positioned between the sacrificial layer 107 of SiGe and etch stop layer 106 of SiGe. In some implementations, the Si layer 109 includes a thickness in a range of 2 nm-8 nm. For example, the Si layer 109 has a thickness of 2 nm. However, other values and ranges are within the scope of the present disclosure. The Si layer 109 may be configured as an etch stop layer.

A deposition tool may be used to deposit the etch stop layer 106, the sacrificial layer 107, the semiconductor layer 108 and/or the etch stop layer 109 by epitaxy. A deposition technique such as chemical vapor deposition (CVD), physical vapor deposition (PVD), and/or atomic layer deposition (ALD) may be used to deposit the etch stop layer 106, the sacrificial layer 107, the semiconductor layer 108 and/or the etch stop layer 109.

In some implementations, the epitaxy operation may be performed at a low temperature, e.g., those below ~750° C., which helps to reduce and/or avoid interdiffusion between the germanium and the silicon in those layers. Silicon precursors such as disilane (Si₂H₆), trisilane (Si₃H₈), and/or tetrasilane (Si₄H₁₀) may be used to deposit the etch stop layer 109 and/or the semiconductor layer 108. Germanium precursors such as digermane (Ge₂H₆) may be used to deposit the etch stop layer 106 and/or the sacrificial layer 107.

In some implementations, an ion implantation tool is used to implant ions into the semiconductor layer 108 to dope the semiconductor layer 108 with one or more types of dopants such as p-type dopants (e.g., boron (B)) and/or n-type dopants (e.g., phosphorous (P) and/or arsenic (As)). In some implementations, the dopant concentration of the semiconductor layer 108 may be included in a range of approximately 1×10¹⁵ atoms per cubic centimeter to approximately 1×10¹⁹ atoms per cubic centimeter. However, other values and ranges are within the scope of the present disclosure.

FIG. 1 shows an example of an n-type device that the semiconductor layer 108 includes silicon and the sacrificial layer 107 includes silicon germanium. In some implementations, for an p-type device as shown in an example implementation in FIG. 1A, a semiconductor layer 208 of SiGe is positioned over a sacrificial layer 207 of SiGe that has a different Ge concentration from the semiconductor layer 208. The semiconductor layer 208 and the sacrificial layer 207 is formed on a composite etch stop layer 205 that includes a first type semiconductor etch stop layer 206 and a second type semiconductor etch stop layer 209. The semiconductor layer 208 may be a same type of semiconductor material as the first type semiconductor etch stop layer 206, e.g., SiGe. The second type semiconductor etch stop layer 209 may be Si. The sacrificial layer 207 of SiGe has a different Ge concentration from that of the semiconductor layer 208 of SiGe, such that each the SiGe layers 208, 207 can be removed selectively with respect to one another. In some implementations, a layer 211 of Si is positioned between the semiconductor layer 208 of SiGe and the sacrificial layer 207 of SiGe. The layer 211 of Si can be configured as an additional etch stop layer to increase the process margin. In some implementations, the layer 211 of Si includes a thickness in a range of 2-8 nm. For example, the layer 211 of Si has a thickness of 4 nm.

In some implementations, in a case that a complementary MOS (CMOS) is made, two different types of epitaxy semiconductor layers can be formed on a same wafer. For example, nFET and pFET regions, e.g., the epitaxy layers of FIG. 1 and FIG. 1A, are formed on the same wafer and are separated by shallow trench isolation (STI) oxide regions.

As shown in FIG. 1B, shallow trench isolation (STI) regions 212 may be formed above the composite etch stop layer 105 including etch stop layers 106 and 109 so that the STI regions 212 define a first type transistor region 214 and a second type transistor region 216. The first type transistor region 214 may be a region of in which an n-type transistor is to be formed, whereas the second type transistor region 216 may be a region in which a p-type transistor is to be formed. The nFET region 214 may include epitaxy layers shown in FIG. 1, and the pFET region 216 may include epitaxy layers shown in FIG. 1A.

In the description hereinbelow, a unipolar process for an nFET region having a fin structure of a semiconductor portion 108 of Si and a sacrificial portion 107 of SiGe is shown and described, for illustrative purposes. It should be appreciated that similar or identical procedures can be applied to make a pFET with a SiGe fin, or to make a CMOS from Si fin for nFET and SiGe fin for pFET, with repeated steps.

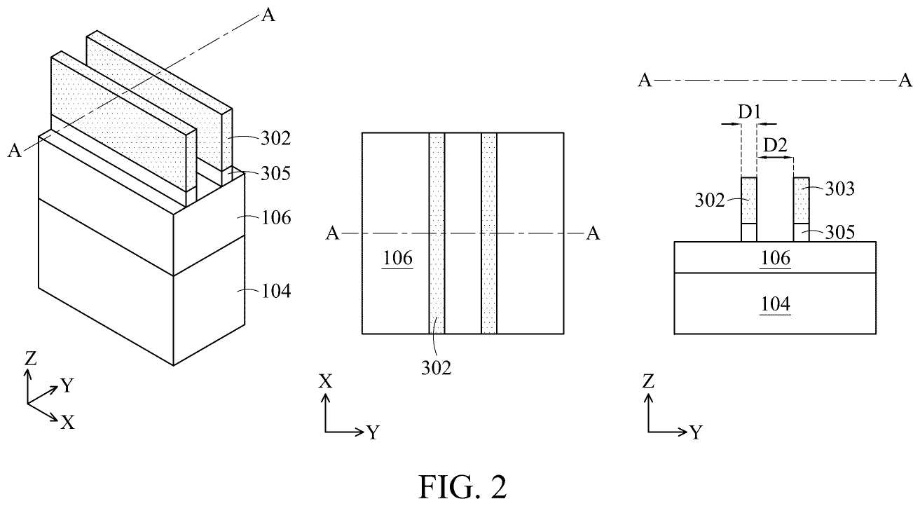

FIG. 2 illustrates an example implementation of a fin formation process described herein, and includes a perspective view, a top view in the x-y plane, and a cross-section view in the y-direction along the line A-A. As shown in FIG. 2, one or more fin structures 302 may be formed from the semiconductor layer 108 and the sacrificial layer 107, e.g., by patterning, and includes a semiconductor portion 303 and a sacrificial portion 305. For example, the semiconductor layer 108 is patterned to form the semiconductor portion 303 and the sacrificial layer 107 is patterned to form the sacrificial portion 305. In some implementations, the semiconductor layer 108 and the sacrificial layer 107 are patterned together to form the semiconductor portion 303 and the sacrificial portion 305. The sacrificial portion 305 may include more than one layers. In some implementations, the sacrificial portion 305 directly abuts the semiconductor portion 303 and is positioned between the semiconductor portion 303 and the etch stop layer 106. The sacrificial portion 305 and the semiconductor portion 303 include materials that have etch selectivity with respect to one another.

The fin structure(s) 302 are semiconductor protruding structures that extend above the semiconductor substrate 104 in the z-direction, and that may extend in (and may be elongated in) in the x-direction in the semiconductor wafer 102. If a plurality of fin structures 302 are formed, the fin structures 302 may be arranged along the y-direction in parallel with one another. Alternatively or additionally, another type of semiconductor protruding structures may be included in the semiconductor wafer 102, such as a protruding layer stacks of nanostructure semiconductor layers (e.g., silicon layers and silicon germanium layers). These layer stacks may be processed to form nanostructure transistors, such as gate all around (GAA) transistors, nanosheet transistors, nanowire transistors, and/or other types of nanostructure transistors.

In some implementations, a pattern in a photoresist layer is used to etch the semiconductor layer 108 and/or the sacrificial layer 107 to form the fin structure(s) 302. In these implementations, a deposition tool may be used to form the photoresist layer on the semiconductor layer 108 (e.g., using a spin-coating technique and/or another suitable deposition technique). An exposure tool may be used to expose the photoresist layer to a radiation source to pattern the photoresist layer. A developer tool may be used to develop and remove portions of the photoresist layer to reveal the pattern. An etch tool may be used to etch the semiconductor layer 108 based on the pattern to form the fin structure(s) 302. In some implementations, a photoresist removal tool may be used to remove the remaining portions of the photoresist layer (e.g., using a chemical stripper, plasma ashing, and/or another technique). In some implementations, the semiconductor layer 108 and the sacrificial layer 107 are patterned together to form the fin structure(s) 302, although other patterning approaches are also possible and included in the scope of the disclosure.

In some implementations, the etch operation includes a dry etch operation (e.g., a plasma-based etch operation, a gas-based etch operation), a wet chemical etch operation, and/or another type of etch operation. The etch operation may stop on the etch stop layer 106. Alternatively, a portion of the etch stop layer 106 may be removed in the etch operation.

In some implementations, a hard mask layer is used as an alternative technique for etching the semiconductor layer 108 based on a pattern. In some implementations, patterning techniques, such as double patterning, triple patterning, quadruple patterning, self-aligned double patterning, and/or self-aligned quadruple patterning may be used to form the fin structures 302.

In some implementations, a fin structure 302 is formed to a width D1 that is included in a range of approximately 4 nanometers to approximately 10 nanometers. In some implementations, D1 is 6 nanometers. However, other values and ranges are within the scope of the present disclosure. In some implementations, fin structures 302 are formed at a pitch D2 that is included in a range of approximately 20 nanometers to approximately 50 nanometers. In some implementations, D2 is 30 nanometers. However, other values and ranges are within the scope of the present disclosure.

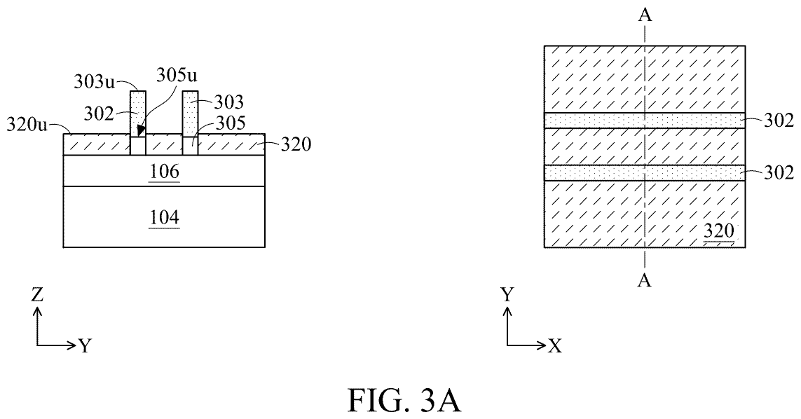

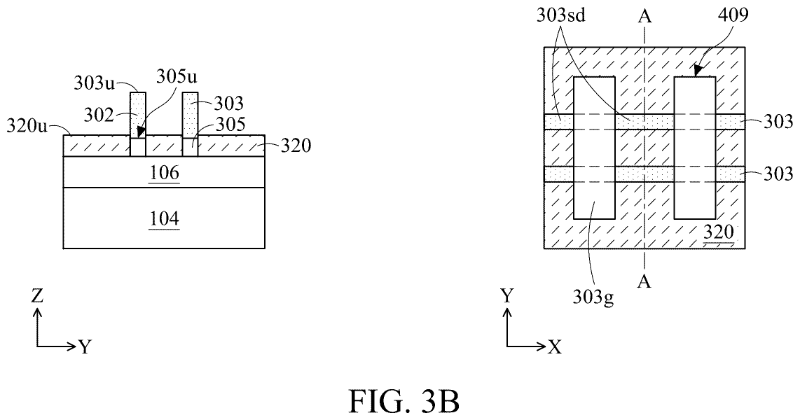

As shown in FIG. 3A, a sacrificial layer 320 is formed adjacent to the fin structure(s) 302. The layer 320 is formed to have a thickness slightly higher than the sacrificial portion 305 of the fin structure 302. As such, upper surface 320u of the layer 320 is above the upper surface 305u of the sacrificial portion 305, with respect to the substrate 104. The layer 320 is adjacent to the semiconductor portion 303 from a lateral direction, x-axis and/or y-axis direction. The upper surface 320u of the layer 320 is below the upper surface 303u of the semiconductor portion 303 of the fin structure 302.

In some implementations, the sacrificial layer 320 is formed by spin coating of an organic material such as high-temperature spin-on-carbon (HTSOC), or other suitable materials. In some implementations, the sacrificial layer 320 is initially deposited to cover the fin structure(s) 302.

After initial deposition, the HTSOC material may be thinned by using a dry etch procedure to a target thickness that is slightly greater than that of the sacrificial portion 305 of the fin structure 302.

As shown in FIG. 3B, in some implementations, after the formation of the sacrificial layer 320, the source or drain regions 303sd of the fin structure(s) 302 may be doped through, a self-aligned doping procedure. The source or drain region 303sd are regions of the semiconductor portion 303 that are adjacent to a gate region 303g of the semiconductor region 303 that is configured to be overlapped by a gate structure. For example, ion implantation of As or P can be implemented on the source or drain regions 303sd of the fin structure 302 for an nFET device and ion implantation of B, In, Ga can be implemented on the source or drain regions 303sd of the fin structure 302 for a pFET device. The self-aligned doping procedure introduce impurities into the source or drain regions 303sd of the fin structure(s) 302. The doping concentration is in a range of approximately 10¹⁹-10²¹ at/cm³. In some implementations, the doping concentration is 10²⁰ at/cm³

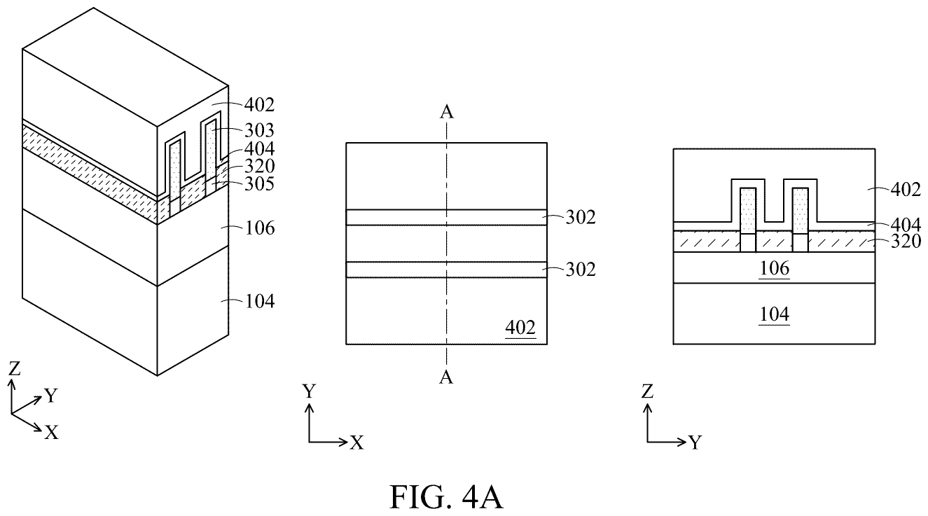

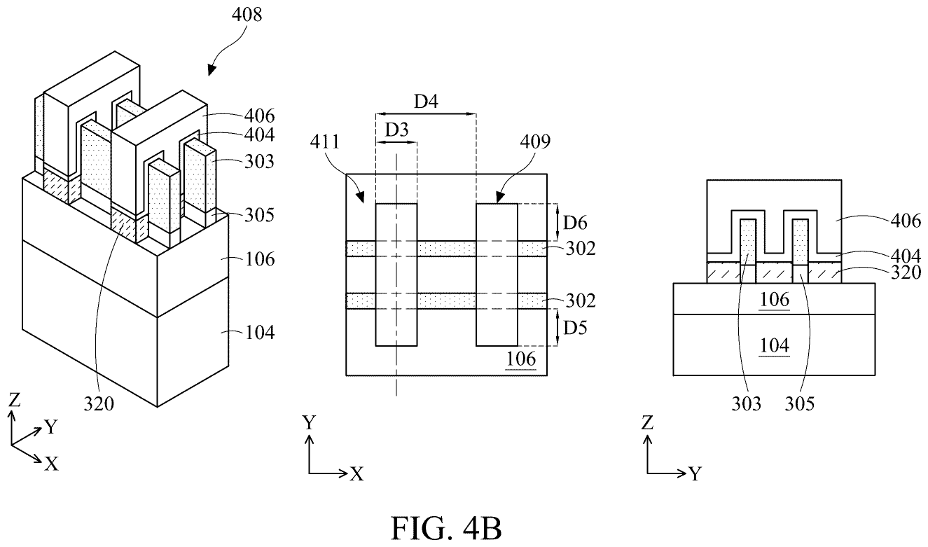

FIGS. 4A and 4B illustrate an example implementation of a dummy gate formation process described herein, and include a perspective view, a top view in the x-y plane, and a cross-section view along the line A-A. As shown in FIG. 4A, a dummy gate stack 402 is formed over the fin structures 302 and on the sacrificial layer 320. The dummy gate stack 402 may include a dummy dielectric layer 404 that is formed over and/or on a front side of the semiconductor wafer 102 such that the dummy dielectric layer 404 is formed on the sidewalls and top surface of the fin structure(s) 302. The front side of the semiconductor wafer 102 is the side of the semiconductor substrate 104 on which the fin structure(s) 302 are formed. The tops of the fin structure(s) 302 are the parts of the fin structure(s) 302 distal from the semiconductor substrate 104 in the z-direction. The bottom of the fin structure(s) 302, specifically, of the sacrificial portion(s) 305, is the part of the fin structure(s) 302 proximate to the semiconductor substrate 104 in the z-direction.

The dummy dielectric layer 404 may include one or more dielectric materials such as silicon oxide (SiOₓ such as SiO₂) and/or silicon nitride (SiₓN_{y} such as Si₃N₄), among other examples. A deposition tool may be used to deposit the dummy dielectric layer 404 using a PVD technique, an ALD technique, a CVD technique, an epitaxy technique, an oxidation technique, and/or another suitable deposition technique. In some implementations, the dummy dielectric layer 404 is formed to a thickness that is included in a range of approximately 1 nanometer to approximately 4 nanometers. For example, the dummy dielectric layer 404 is formed to a thickness of approximately 2 nm. However, other values and ranges are within the scope of the present disclosure.

As further shown in FIG. 4A, the dummy gate stack 402 may include a dummy electrode layer 406 that is formed on the front side of the semiconductor wafer 102 such that the dummy electrode layer 406 is formed over and/or on the dummy dielectric layer 404. The dummy electrode layer 406 may include polysilicon and/or some other suitable material.

The dummy electrode layer 406 may be blanket deposited such that the dummy electrode layer 406 covers the fin structure(s) 302. A deposition tool may be used to deposit the dummy electrode layer 406 using a PVD technique, an ALD technique, a CVD technique, an epitaxy technique, an oxidation technique, and/or another suitable deposition technique. In some implementations, a planarization tool may be used to perform a planarization operation (e.g., a chemical-mechanical planarization (CMP) operation) to planarize the dummy electrode layer 406. In some implementations, the dummy electrode layer 406 is formed to a thickness that is included in a range of approximately 40 nanometers to approximately 200 nanometers. For example, the dummy electrode layer 406 is formed to a thickness of approximately 100 nm. However, other values and ranges are within the scope of the present disclosure.

As shown in FIG. 4B, the dummy dielectric layer 404 and the dummy electrode layer 406 may be patterned, e.g., etched, to define one or more dummy gate structures 408 of the semiconductor wafer 102. A dummy gate structure 408 is a temporary gate structure that is formed as a placeholder for a gate structure (e.g., a metal gate structure) of a transistor of the semiconductor wafer 102. The dummy gate structure 408 temporarily occupies a space, referred to as a gate region 409, for the gate structure and acts as a sacrificial structure during formation of other layers and/or structures of the semiconductor wafer 102. In this way, eventual damage arising from these processes is absorbed by the dummy gate structure 408 as opposed to the gate structures of the transistors, thereby minimizing the damage to the gate structures.

In some implementations, the patterning of the dummy dielectric layers 406 and 404 also patterns the sacrificial layer 320 such that the remaining sacrificial 320 partially overlaps or abuts the dummy gate structure 408 in the gate region 409. Outside of the gate region 409, referred to herein as the non-gate region 411, the sacrificial layer 320 is removed.

A dummy gate structure 408 extends in the y-direction in the semiconductor device and wraps around the tops and sides of the fin structure(s) 302. In some implementations, a dummy gate structure 408 wraps around three sides of a fin structure 302. In implementations in which a plurality of dummy gate structures 408 are formed, the dummy gate structures 408 may be arranged in the x-direction. In this way, the dummy gate structures 408 extend in an approximately orthogonal direction to the fin structure(s) 302, such that the dummy gate structures 408 cross over one or more fin structures 302.

In some implementations, a pattern in a photoresist layer is used to etch the dummy dielectric layer 404 and the dummy electrode layer 406 to form the dummy gate structure(s) 408. In these implementations, a deposition tool may be used to form the photoresist layer on the dummy electrode layer 406 (e.g., using a spin-coating technique and/or another suitable deposition technique). An exposure tool may be used to expose the photoresist layer to a radiation source to pattern the photoresist layer. A developer tool may be used to develop and remove portions of the photoresist layer to expose the pattern. An etch tool may be used to etch the dummy dielectric layer 404 and the dummy electrode layer 406 based on the pattern to form the dummy gate structure(s) 408. In some implementations, the etch operation includes a dry etch operation (e.g., a plasma-based etch operation, a gas-based etch operation), a wet chemical etch operation, and/or another type of etch operation. In some implementations, a photoresist removal tool may be used to remove the remaining portions of the photoresist layer (e.g., using a chemical stripper, plasma ashing, and/or another technique). In some implementations, a hard mask layer is used as an alternative technique for forming the dummy gate structures 408 based on a pattern.

As shown in FIG. 4B, a dummy gate structure 408 may have a gate length (indicated in FIG. 4B as dimension D3) that is included in a range of approximately 10 nanometers to approximately 40 nanometers. For example, the gate length is approximately 16 nm. However, other values and ranges are within the scope of the present disclosure. A pitch between adjacent dummy gate structures 408 (indicated in FIG. 4B as dimension D4) may be included in a range of approximately 28 nanometers to approximately 56 nanometers. For example, the gate pitch is approximately 42 nm. However, other values and ranges are within the scope of the present disclosure. In some implementations, opposing ends of a dummy gate structure 408 may extend laterally outward from fin structures 302 by approximately the same distance. In some implementations, opposing ends of a dummy gate structure 408 may extend laterally outward from fin structures 302 asymmetrically such that a first distance of a first end (indicated in FIG. 4B as dimension D5) and a second distance of a second end (indicated in FIG. 4B as dimension D6) are different distances.

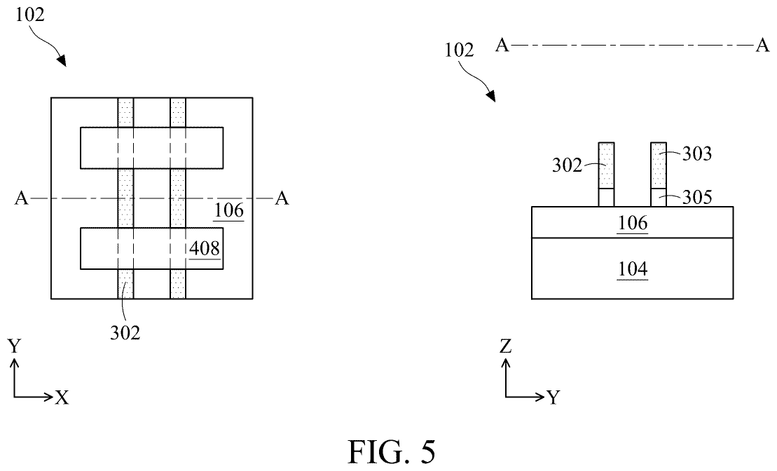

Alternative or in addition to the fin doping process of FIG. 3B, FIG. 5 illustrates an example implementation of a fin doping process after the dummy gate structure 408 has been formed. FIG. 5 includes a top view in the x-y plane and a cross-section view in the y-direction along the line A-A. As shown in FIG. 5, an ion implantation operation may be performed to dope one or more of the fin structures 302, e.g., the semiconductor portion 303 thereof, with one or more types of dopants. In some implementations, a fin structure 302 for an n-type transistor may be doped with n-type dopants such as arsenic (As) and/or phosphorous (P), among other examples. In some implementations, a fin structure 302 for a p-type transistor may be doped with p-type dopants such as boron (B), indium (In), and/or gallium(Ga), among other examples. In some implementations, a fin structure 302 may be doped to have a dopant concentration that is included in a range of approximately 1×10¹⁹ atoms per cubic centimeter to approximately 1×10²¹ atoms per cubic centimeter. However, other values and ranges are within the scope of the present disclosure.

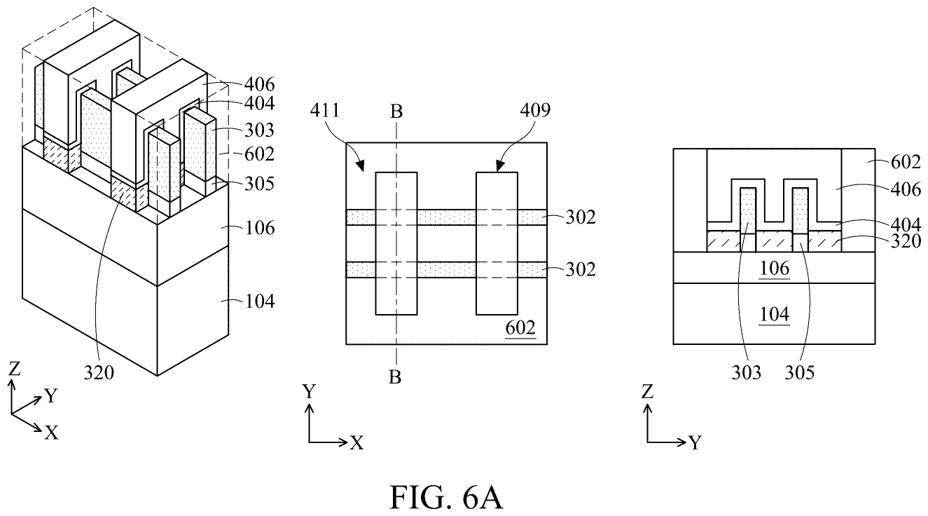

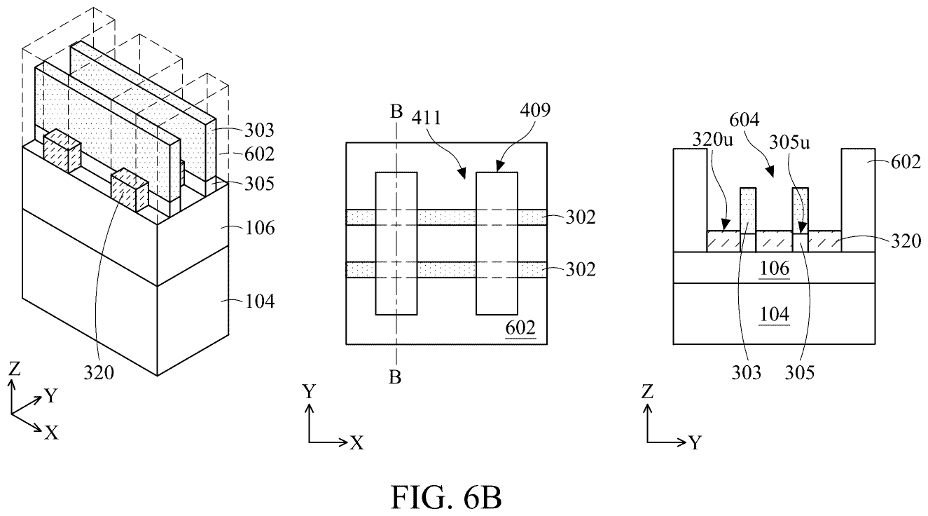

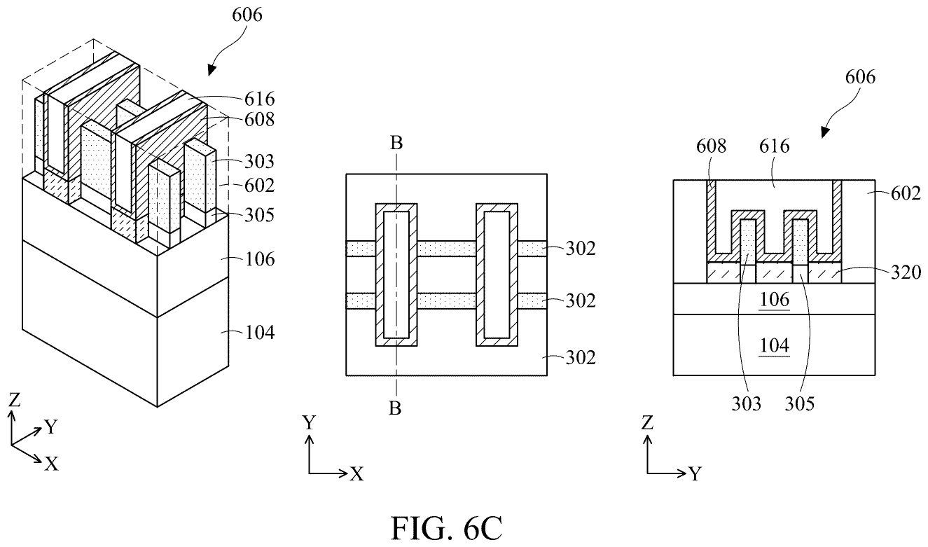

FIGS. 6A-6C illustrate an example implementation of replacement gate process described herein, and include a perspective view, a top view in the x-y plane, and a cross-section view in the y-direction along the line B-B. The line B-B is along a dummy gate structure 408 in the y-direction. As shown in FIGS. 6A-6C, the replacement gate process includes replacing the dummy gate structures 408 with gate structures (e.g., metal gate structures) 606 (FIG. 6C) of the transistors of the semiconductor wafer 102.

As shown in FIG. 6A, an interlayer dielectric (ILD) layer 602 may be deposited around the dummy gate structures 408. In some implementations, the ILD layer 602 is deposited with a thickness of 100-400 nm (e.g., 200 nm) such that the ILD layer 602 covers the dummy gate structures 408, and a planarization tool is used to perform a planarization operation (e.g., a CMP operation) such that the tops of the dummy gate structures 408 are exposed and such that the top 602u of the ILD layer 602 is approximately at a same level with the tops 402u of the dummy gate structure 408. As the sacrificial layer 320 has been patterned and removed from non-gate region 411, the ILD layer 602 surrounds the fin structure 302 including the sacrificial portion 305 and the semiconductor portion 303 in the non-gate region 411.

The ILD layer 602 may include one or more dielectric materials such as silicon oxide (SiOₓ such as SiO₂) and/or silicon nitride (SiₓN_{y} such as Si₃N₄), among other examples. A deposition tool may be used to deposit the ILD layer 602 using a PVD technique, an ALD technique, a CVD technique, an epitaxy technique, an oxidation technique, and/or another suitable deposition technique.

As shown in FIG. 6B, one or more etch operations may be performed to remove the dummy gate structures 408. This leaves behind openings 604 in which portions of the fin structures 302 are exposed. In some implementations, the sacrificial layer 320 remain within the openings 604 and the upper surface 320U of the sacrificial layer 320 remain slightly higher than the upper surfaces 305u of the sacrificial portions 305 of the fin structures 302.

As shown in FIG. 6C, gate structures 606 are formed in the openings 604 left behind by removal of the dummy gate structures 408. Thus, the gate structures 606 are formed on the front side of the semiconductor wafer 102 such that the gate structures 606 wrap around the tops and sidewalls of the fin structures 302 and are positioned on the sacrificial layer 320. A small portion of the semiconductor portion 303 and the sacrificial portion 305 of the fin structure(s) 302 extend downwardly beyond the gate structure 606. The gate structures 606 may extend in the y-direction and may be arranged in the x-direction. In some implementations, a gate structure 606 may extend across a plurality of fin structures 302.

A gate structure 606 may include a conformal layer stack 608 that conforms to the profile of the fin structures 302. The conformal layer stack 608 may include one or more of an interfacial layer, a gate dielectric layer, or a work function metal layer, among other examples. A gate structure may further include a gate electrode layer 616 that fills in the remaining areas of the openings 604.

The interfacial layer may include an oxide layer that is formed from a chemical reaction with the surface of the fin structures 302. For example, a chemical oxidation process using ozone (O₃) in combination with hydrofluoric acid (HF) and/or hydrochloric acid (HCl) may be used to oxidize the exposed portions of the fin structures 302 in the openings 604 to form the interfacial layer.

Additionally or alternatively, the interfacial layer may be formed by a thermal oxidation process, such as by rapid thermal anneal (RTA). The semiconductor wafer 102 may be placed in a processing chamber, and an oxygen-containing gas may be provided into the processing chamber for the RTA process. In some implementations, an in-situ steam generation (ISSG) technique is used for the thermal oxidation process.

In some implementations, the interfacial layer is formed by deposition, and a deposition tool may be used to deposit the interfacial layer using an ALD technique, a CVD technique, and/or another suitable deposition technique.

In some implementations, the interfacial layer is formed to a thickness that is included in a range of approximately 0.2 nanometers to approximately 2 nanometers. However, other values and ranges are within the scope of the present disclosure. After the interfacial layer is formed, an anneal may be performed in a hydrogen-containing environment and/or with a hydrogen-based plasma to passivate dangling bonds at the interface between the interfacial layer and the fin structures 302.

The gate dielectric layer may include a high dielectric constant (high-k) dielectric material having a dielectric constant that is greater than approximately 3.9. Such high-k dielectric materials may include hafnium oxide (HfOₓ such as HfO₂), aluminum oxide (AlₓO_{y} such as Al₂O₃), zirconium oxide (ZrOₓ such as ZrO₂), hafnium zirconium oxide (HfZrOₓ), hafnium silicon oxide (HfSiOₓ), lanthanum oxide (LaₓO_{y} such as La₂O₃), and/or titanium oxide (TiOₓ such as TiO₂), among other examples. Additionally and/or alternatively, the gate dielectric layer may include one or more low dielectric constant (low-k) dielectric materials such as silicon oxide (SiOₓ such as SiO₂).

In some implementations, the gate dielectric layer is formed by deposition, and a deposition tool may be used to deposit the gate dielectric layer using an ALD technique, a CVD technique, and/or another suitable deposition technique. In some implementations, the gate dielectric layer is formed to a thickness that is included in a range of approximately 1 nanometer to approximately 4 nanometers. However, other values and ranges are within the scope of the present disclosure.

After the gate dielectric layer is deposited, an anneal may be performed on the gate dielectric layer to cure bulk defects in the gate dielectric layer. The anneal may be performed in an environment that contains hydrogen gas, oxygen gas, and/or nitrogen gas, among other examples.

The work function metal layer may include one or more metals and/or one or more metal alloys that are included for tuning the work function of the gate structure 606. In some implementations, a work function metal layer of an n-type transistor may include an n-type metal that tunes or adjusts the work function of the gate structure 606 of the n-type transistor near the conduction band of the material of the fin structure(s) 302. Examples of such n-type metals include titanium aluminum (TiAl), titanium aluminum carbon (TiAlC), and/or another aluminum-containing metal, among other examples. In some implementations, a work function metal layer of a p-type transistor may include one or more p-type metals, such as titanium nitride (TiN), tungsten nitride (WN), and/or another metal having a work function that is greater than approximately 4.7 eV, among other examples. The p-type metal may be included to tune the work function of the p-type transistor such that the work function is adjusted close to the valance band of the material of the fin structure(s) 302.

In some implementations, the work function metal layer is formed by deposition, and a deposition tool may be used to deposit the work function metal layer using an ALD technique, a CVD technique, and/or another suitable deposition technique. In some implementations, the work function metal layer is formed to a thickness that is included in a range of approximately 2 nanometers to approximately 8 nanometers. However, other values and ranges are within the scope of the present disclosure.

The gate electrode layer 616 may include one or more metals, such as tungsten (W), titanium (Ti), and/or copper (Cu), among other examples. In some implementations, the gate electrode layer 616 is formed by deposition, and a deposition tool may be used to deposit the gate electrode layer 616 using an ALD technique, a CVD technique, and/or another suitable deposition technique. In some implementations, a planarization tool is used to planarize the gate structures 606 after the gate electrode layer 616 is deposited.

FIGS. 1-6C illustrate front side process operations for the semiconductor wafer 102, in which the fin structures 302 and gate structures 606 are formed on a first side, e.g., front side, of the semiconductor wafer 102.

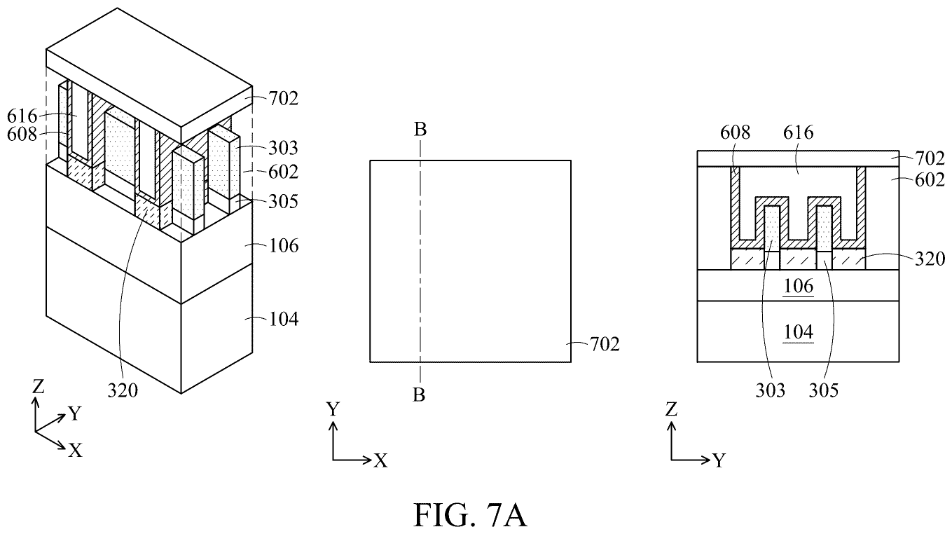

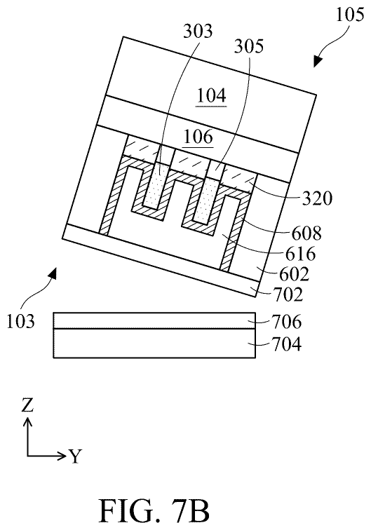

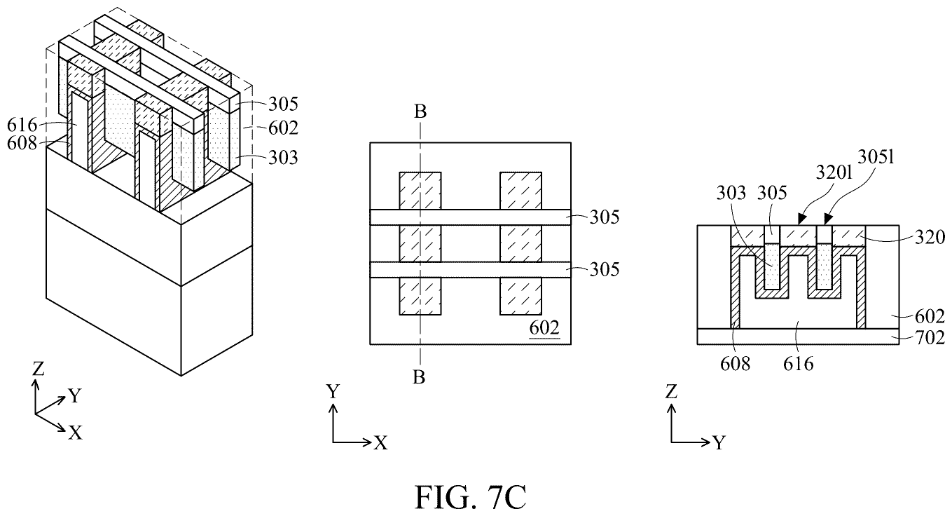

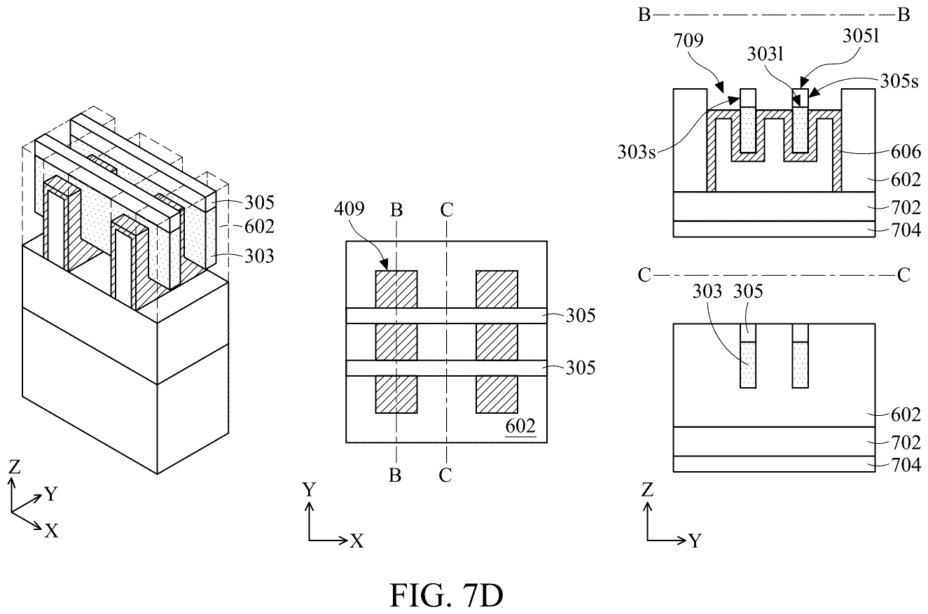

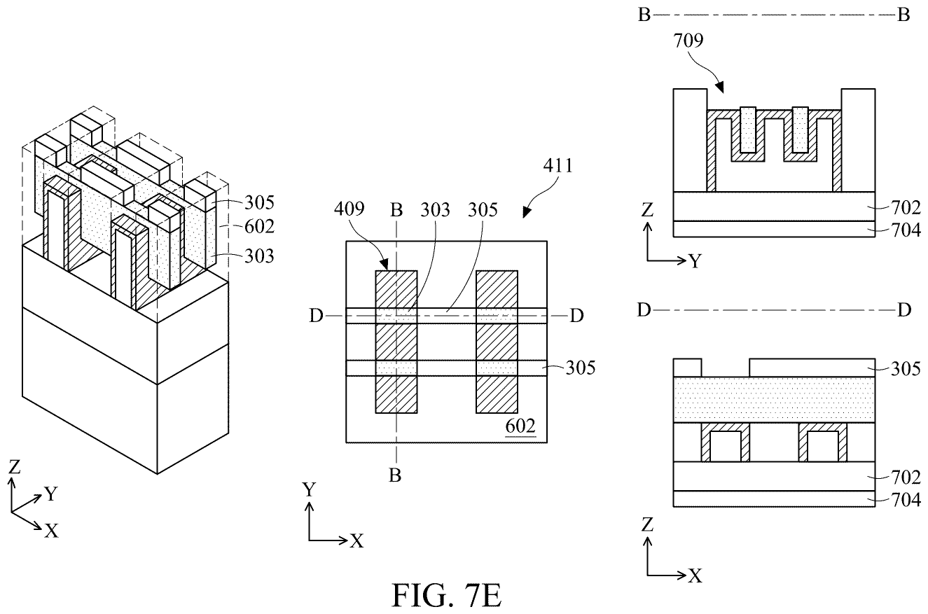

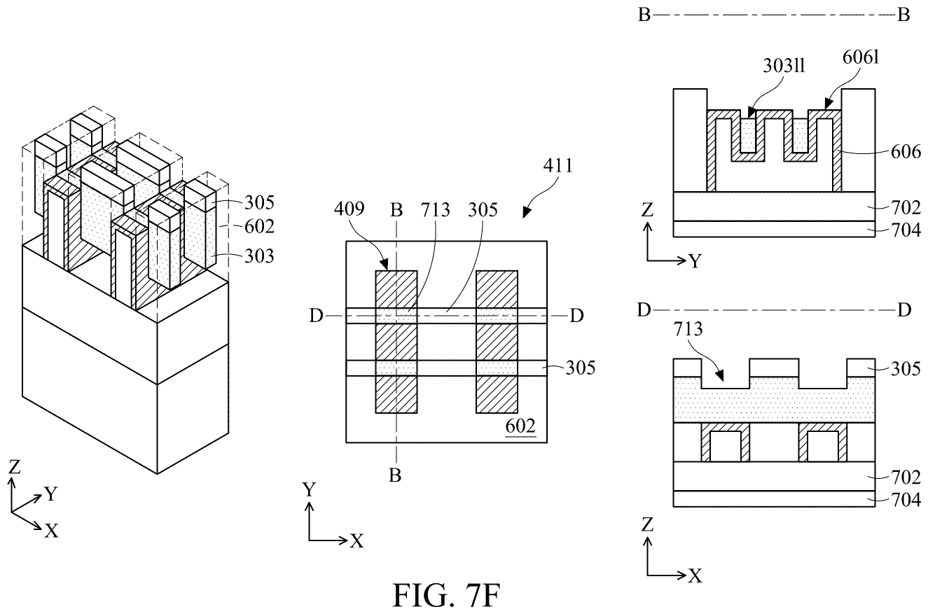

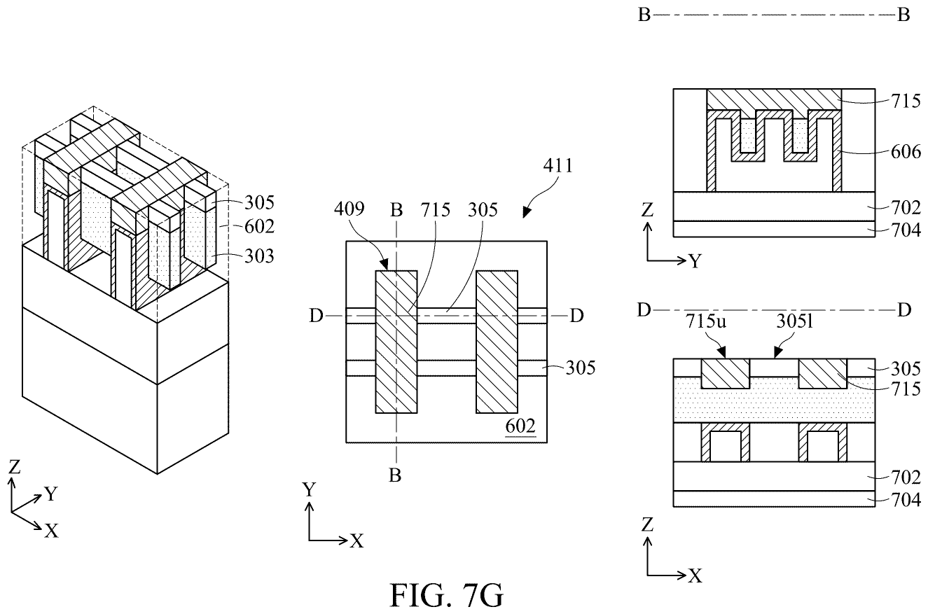

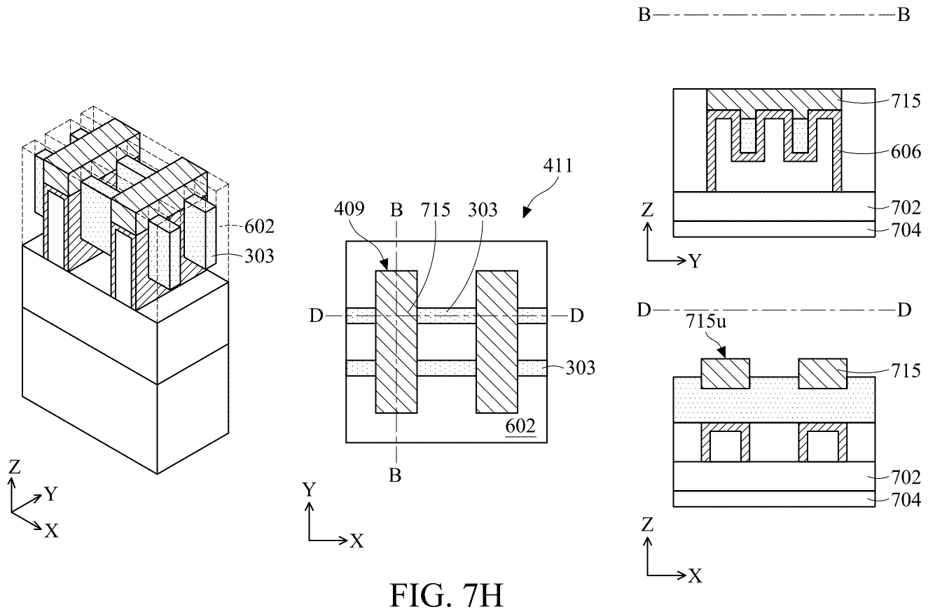

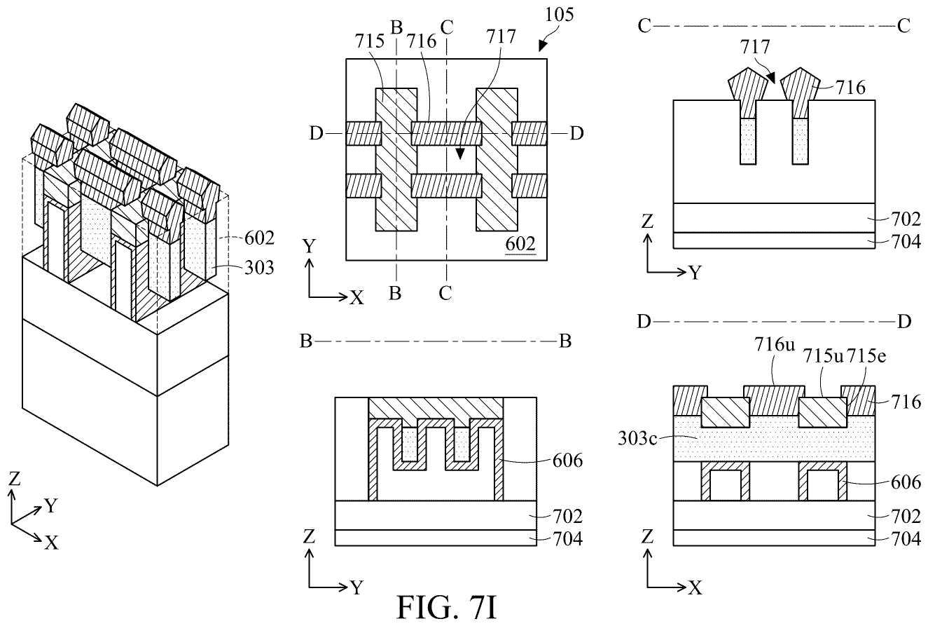

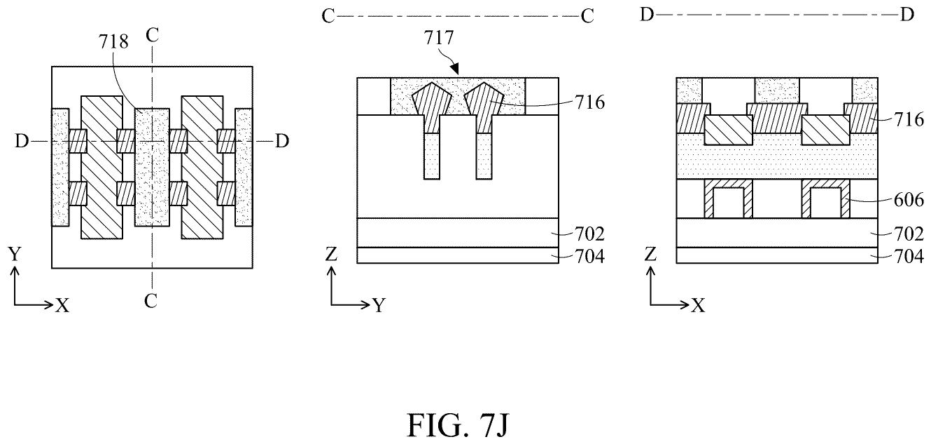

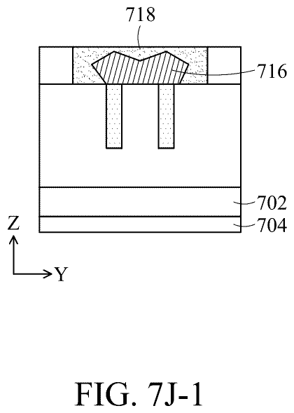

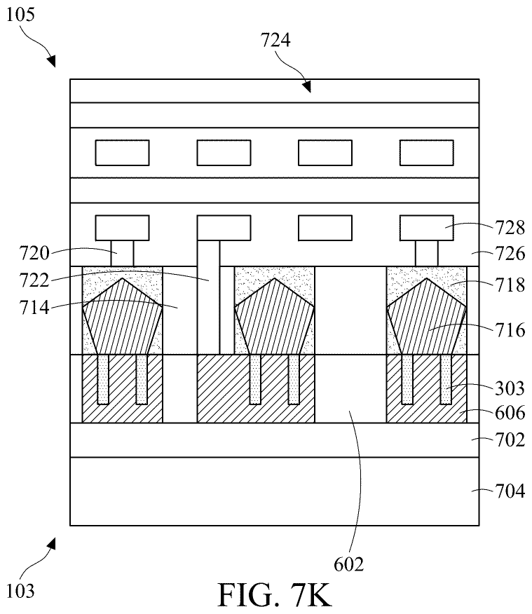

FIGS. 7A-7K illustrate an example implementation of back side processing of the semiconductor wafer 102, in which source/drain structures and source/drain contacts of the transistors are formed on a second side, e.g., the back side, of the semiconductor wafer 102 that is opposite to the first side. In this way, the source/drain contacts and the gate structures 606 are located on opposing sides of the fin structures 302 (e.g., the gate structures 606 are located on the front side, or tops, of the fin structures 302, and the source/drain contacts are located on the back side, or bottoms, of the fin structures 302) so that gate spacers can be omitted.

FIGS. 7A-7K include perspective views, top views in the x-y plane, and cross-section views in the y-direction along one or more of line B-B, line C-C, or line D-D, as applicable. The line B-B is along a gate structure 606 in the y-direction. The line C-C crosses multiple fin structures 302 in a non-gate region. The line D-D is along a fin structure 302 and across a plurality of gate structures the x-direction.

As shown in FIGS. 7A and 7B, a bonding layer 702 may be formed on the front side of the semiconductor wafer 102 so that the bonding layer 702 can be used to bond the front side of the semiconductor wafer 102 to a carrier substrate 704. To bond the semiconductor wafer 102 to the carrier substrate 704, a bonding tool may be used to perform a bonding operation to bond the bonding layer 702 on the front side of the semiconductor wafer 102 to on the carrier substrate 704.

FIG. 7B depicts the semiconductor wafer 102 after the bonding operation, flipped, with the semiconductor substrate now facing up. As shown in FIG. 7B, the bonding layers 702 and 706 may merge to form a bonding layer 708. In some implementations, a bonding interface 710 between the bonding layers 702 and 706 is visible in the semiconductor wafer 102. In some implementations, no bonding interface is visible, and the bonding layers 702 and 706 merge into a singular layer, referred to as layer 702 herein for descriptive purposes.

The bonding layers 702 and 706 may each include one or more dielectric materials, such as silicon oxide (SiOₓ such as SiO₂), silicon nitride (SiₓN_{y} such as Si₃N₄), and/or silicon carbonitride (SiCN), among other examples. A deposition tool may be used to deposit the bonding layers 702 and 706 using an ALD technique, a CVD technique, and/or another suitable deposition technique. In some implementations, a planarization tool is used to planarize the bonding layers 702 and/or 706 after the bonding layers 702 and/or 706 is deposited. In some implementations, a thickness of the bonding layer 702 and/or a thickness of the bonding layer 706 may be included in a range of approximately 10 nanometers to approximately 100 nanometers. However, other values and ranges are within the scope of the present disclosure.

As further shown in FIG. 7B, the semiconductor wafer 102 is bonded to the carrier substrate 704 such that the first side (e.g., front side) 103 of the semiconductor wafer 102 is facing the carrier substrate 704, and such that the second side (e.g., back side) 105 of the semiconductor wafer 102 is facing away from the carrier substrate 704. This enables back side processing to be performed on the semiconductor wafer 102.

In some implementations, after the bonding of the bonding layers 702 and the carrier substrate 704, a curing anneal is conducted to strengthen the dielectric bond.

As shown in FIG. 7C, back side processing of the semiconductor wafer 102 may include removing the semiconductor substrate 104 and the etch stop layer 106 from the back side of the semiconductor wafer 102. In some implementations, an etch tool is used to perform an etch operation to etch the semiconductor substrate 104 and/or the etch stop layer 106 to remove the semiconductor substrate 104 and/or the etch stop layer 106. In some implementations, a planarization tool (e.g., a CMP tool) is used to perform a planarization operation to remove the semiconductor substrate 104 and/or the etch stop layer 106. In some implementations, a planarization tool (e.g., a wafer grinding tool) is used to perform a grinding operation to remove the semiconductor substrate 104 and/or the etch stop layer 106. In some implementations, the etch operation, the planarization operation, and/or the grinding operation is stopped once the bottoms of the fin structures 302, or the bottoms of the sacrificial portions 305 of the fin structures 302, are exposed on the back side of the semiconductor wafer 102. The sacrificial layer 320 is also exposed on the back side of the semiconductor wafer 102. In some implementations, the exposed sacrificial portions 305, e.g., surface 305l, and the exposed sacrificial layer 320, e.g., surface 320l, are on a same level as one another.

FIG. 7D illustrates that the sacrificial layer 320 of, e.g., HTSOC material, is removed using dry etch, which generates an open area 709 corresponding to the gate region 409. After the sacrificial layer 320 has been removed, the surface 305l and the sidewall surface 305s of the sacrificial portion 305 of the fin structure 302 are exposed to air in the open area 709 that correspond to the gate region 409, and sidewall surface 303s of the semiconductor portion 303 is also partially exposed to air in the open area 709. Note that before the removal, the sacrificial layer 320 is adjacent to the portion 303l of the semiconductor portion 303 of the fin structure 302. In the non-gate area 411, the fin structures 302 including the sacrificial portion 305 and the portion 303l of the semiconductor portion 303 remain surrounded by the dielectric layer 602, e.g., SiO2.

As shown in FIG. 7E, the sacrificial portion 305 of the fin structure 302 in the open area 709 is removed by, e.g., wet etch. In some implementations, the removal of the sacrificial portion 305 from the open area 709 may also slightly remove or recess the sacrificial portion 305 from the non-gate region 411 adjacent to the open area 709.

FIG. 7F illustrates that after the sacrificial portion 305 of the fin structure 302 has been removed from the open area 709, the semiconductor portion 303 of the fin structure 302 is recessed, e.g., using a dry etch, to a level that is below the gate structure 606. The remaining sacrificial portion 305, e.g., in the non-gate area 411, is used as an etch stop layer or a mask for the dry etching. In some implementations, the semiconductor portion 303 is recessed to a level 303ll that is approximately 5 nm below the adjacent surface 606L of the gate structure 606. However, other values and ranges are possible and included within the scope of the present disclosure. In some implementations, because parts of the sacrificial portion 305 in the non-gate area 411 adjacent to the open area 709 is also removed or recessed, the semiconductor portion 303 below the removed parts of the sacrificial portion 305 in the non-gate area 411 is also recessed. The recessing generates a recessed portion 713 in the semiconductor portion 303 of the fin structure 302 that is generally in the gate region 409 and corresponds to and overlaps the gate structure 606.

FIG. 7G illustrates that a dielectric layer 715, e.g., of SiO₂, is formed in the open area 709. The dielectric layer 715 fills in the recessed portion 713 of the semiconductor portion 303 and the open area 709. The dielectric layer 715 is also on the gate structure 606 as the gate structure 606 is exposed in the open area 709. The upper surface 715u of the dielectric layer 715 is at a same level as the surface 305l of the remaining sacrificial portion 305 of the fin structure 302. For example, the dielectric layer 715 may be blanketly deposited and then polished or thinned to the level 305l of the remaining sacrificial portion 305. After the thinning/polishing, the remaining sacrificial portion 305 is exposed from the dielectric layer 715. In some implementations, to make sure that the remaining sacrificial portion 305 is exposed from the dielectric layer 715, a slight over-polish may be done, which actually removes a thin portion of the remaining sacrificial portion 305.

A deposition tool may be used to deposit the dielectric layer 715 using a PVD technique, an ALD technique, a CVD technique, an epitaxy technique, an oxidation technique, and/or another suitable deposition technique. A planarization tool is used to perform a planarization operation (e.g., a CMP operation) to planarize the dielectric layer 715.

FIG. 7H illustrates that the remaining sacrificial portion 305 is removed using wet etch or dry etch. The removal of the remaining sacrificial portion 305 exposes semiconductor portion 303 of the fin structure 302 adjacent to the recessed portion 713 that is filled by the dielectric layer 715. The exposed semiconductor portion 303, e.g., surface 303l, is lower than surface 715u of the dielectric layer 715, due to the removal of the remaining sacrificial portion 305. Note that before the removal, the remaining sacrificial portion 305 and the dielectric layer 715 are on a same level as one another.

As shown in FIG. 7I, source/drain structures 716 of one or more transistors are formed on the back side 105 of the semiconductor wafer 102. For example, source/drain structures 716 are formed on the exposed semiconductor portions 303 of the fin structures 302. Thus, the source/drain structures 716 are formed on the bottoms of the fin structures 302. The term “source/drain structure(s)” may refer to a source or a drain, individually or collectively, as applicable upon the context.

The source/drain structures 716 are separated from one another laterally by the dielectric layer 715. The dielectric layer 715 overlaps the gate structure 606 in the vertical, e.g., z-axis, direction. The source/drain structures 716 are adjacent to two sides of the dielectric layer 715. As such, the channel region 303c of the semiconductor portion 303 of the fin structure 302 is aligned with the gate structure 606 and is positioned between two source/drain structures 715 on the same fin structure 302.

In some implementations, the source/drain structures 716 may be formed to have an upper surface 716u that is higher than the upper surface 715u of the dielectric layer 715. In some implementations, the source/drain structure 716 overlaps edge portions 715e of the dielectric layer 715, although the source/drain structures 716 on the two sides of the dielectric layer 715 still do not contact one another and are separated from one another.

Forming a source/drain structure 716 may include epitaxially growing semiconductor material on the exposed portions of the semiconductor portion 303 of the fin structures 302, e.g., the portions of the semiconductor portion 303 that are not covered by the dielectric layer 715 and adjacent to the dielectric layer 715. In some implementations, a source/drain structure 716 may be doped with one or more types of dopants. For example, a source/drain structure 716 for an n-type transistor may be silicon, doped with n-type dopants such as arsenic (As) and/or phosphorous (P), among other examples. As another example, a source/drain structure 716 for a p-type transistor may be silicon or silicon germanium, doped with p-type dopants such as boron (B), indium (In), and/or gallium(Ga), among other examples.

In some implementations, as shown in FIG. 7I, the source/drain structure 716 formed on separate fin structures 302 are separated from one another. There is a gap 717 between source/drain structures 716 formed on two adjacent fin structures 302, specifically semiconductor portions 303 of the two adjacent fin structures 302. In some other implementations, as shown in FIG. 7J-1, the source/drain structures 716 formed on two adjacent fin structures 302 merge with one another. For example, the epitaxy growth of the source/drain structures 716 on two adjacent fin structures 302 abut one another or are integral to one another. A merged source/drain structure 716 may be formed on a plurality of fin structures 302 such that the merged source/drain structure 716 extends across the plurality of fin structures 302. The merged source/drain structure 716 may be formed by epitaxially growing source/drain structures 716 on the plurality of fin structures 302 until the source/drain structures 716 merge to form the merged source/drain structure 716.

As shown in FIG. 7J, source/drain contacts 718 may be formed on and/or around the source/drain structures 716. The source/drain contacts 718 may include vias, plugs, and/or another type of electrically conductive structures. The source/drain contacts 718 may include tungsten (W), cobalt (Co), ruthenium (Ru), titanium (Ti), titanium nitride (TiN), aluminum (Al), and/or gold (Au), among other electrically conductive materials. A deposition tool may be used to deposit the source/drain contacts 718 using a PVD technique, an ALD technique, a CVD technique, and/or another suitable deposition technique. The source/drain contacts 718 may be deposited in one or more deposition operations. A source/drain contact 718 may be deposited on the top of, and/or around the sides of, a source/drain structure 716.

In some implementations, the source/drain contacts 718 each may extend across source/drain structures 716 of multiple fin structures 302, e.g., two fin structure 302 shown in FIG. 7J as illustrative examples. For example, the source/drain contacts 718 may fill in the gap 717 between two source/drain structures 716 formed on two adjacent fin structures 302. In some other implementations, the source/drain structures 716 formed on adjacent fin structures 302 may merge into one another and the source/drain contacts 718 may be adjacent to more than one sides of the merged source/drain structure 716, as shown in FIG. 7J-1.

In some implementations, a metal silicide layer (not shown) is formed at the interface between source/drain structure 716 and source/drain contact 718, and a source/drain contact 718 is formed on the metal silicide layer. The metal silicide layer may be formed by depositing a layer of metal on the bottom of the fin structure 302, such as a layer of titanium and/or a layer of ruthenium, and performing an annealing operation to cause the layer of metal to diffuse into the surface of the bottom of the fin structure 302.

As further shown in FIG. 7K, source/drain interconnects 720 may be formed on the source/drain contacts 718. The source/drain interconnects 720 may include vias, conductive pillars, conductive columns, and/or another type of electrically conductive structures. The source/drain interconnects may include copper (Cu), tungsten (W), cobalt (Co), ruthenium (Ru), titanium (Ti), aluminum (Al), and/or gold (Au), among other electrically conductive materials.

A deposition tool may be used to deposit the source/drain interconnects 720 using a PVD technique, an ALD technique, a CVD technique, and/or another suitable deposition technique.

As further shown in FIG. 7K, gate interconnects 722 may be formed on and/or around the gate structures 606. The gate interconnects 722 may include vias, conductive pillars, conductive columns, and/or another type of electrically conductive structures. The source/drain interconnects may include copper (Cu), tungsten (W), cobalt (Co), ruthenium (Ru), titanium (Ti), aluminum (Al), and/or gold (Au), among other electrically conductive materials. A deposition tool may be used to deposit the gate interconnects 722 using a PVD technique, an ALD technique, a CVD technique, and/or another suitable deposition technique.

As shown in FIG. 7K, in an example implementation, the source/drain contacts 718, the source/drain interconnects 720, and the gate interconnects 722 are formed on the back side of the semiconductor wafer 102. The source/drain interconnects 720, and the gate interconnects 722 may be formed as part of an interconnect layer 724 formed on the back side of the semiconductor wafer 102. Therefore, the interconnect layer 724 may be referred to as a back side interconnect layer 724 (or a back side back end of line (BEOL) region).

The source/drain interconnects 720 may be formed in an ILD layer 726 of the interconnect layer 724. The gate interconnects 720 may be formed in an ILD layer 726 of the interconnect layer 724 and may extend to underlying gate structures 606 on the front side 103 of the semiconductor wafer 102 through any ILD layer 714 on the backside 105 of the semiconductor wafer 102. Therefore, the gate interconnects 720 may extend between the front side and the back side of the semiconductor device.

The source/drain interconnects 720 and the gate interconnects 722 may be electrically connected to conductive structures 728 in the interconnect layer 724. The conductive structures 728 provide electrical routing that enables signals and/or power to be distributed throughout the semiconductor wafer 102. The conductive structures 728 may include a combination of trenches, metallization layers, conductive traces, vias, interconnects, and/or other types of conductive structures. The conductive structures 728 may each include one or more electrically conductive materials such as tungsten (W), cobalt (Co), ruthenium (Ru), titanium (Ti), aluminum (Al), copper (Cu), gold (Au), and/or a combination thereof, among other examples of electrically conductive materials.

As shown in FIG. 7K, the semiconductor wafer 102 may include a semiconductor portion 303 of a fin structure 302, a gate structure 606 on a first side of the fin structure 302, a source/drain structure 716 on a second side 105 of the fin structure 302 vertically opposing the first side, a source/drain contact 718 on the source/drain structure 716 above the second side of the fin structure 302, a source/drain interconnect 720 on the source/drain contact 718 above the second side of the fin structure 302, and a gate interconnect 722 extending from the second side to the gate structure 606 on the first side. An ILD layer 602 may be laterally adjacent to the gate structure 606 and may be in contact with the gate structure 606, and an ILD layer 714 laterally adjacent to the source/drain structure 716 may be in contact with the source/drain structure 716.

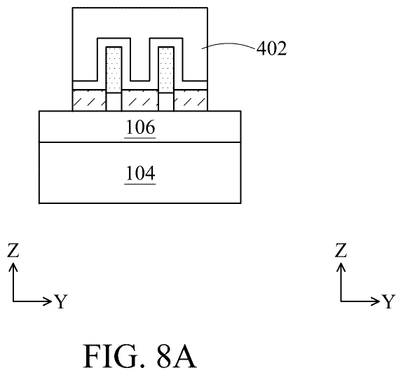

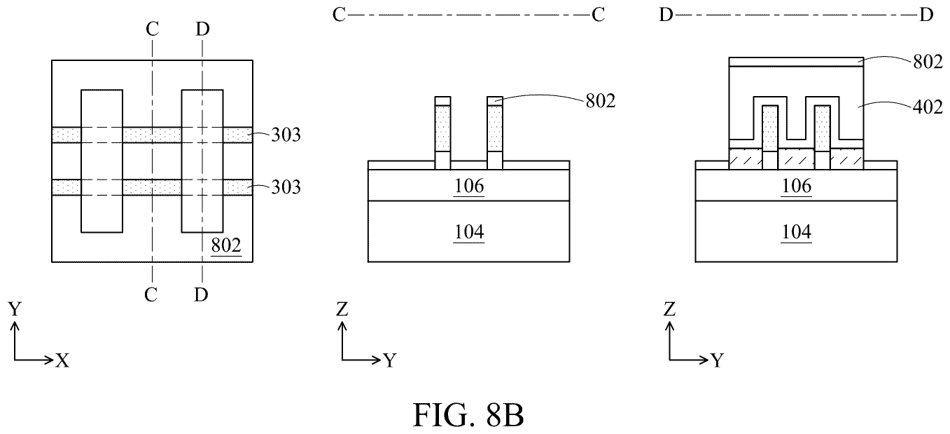

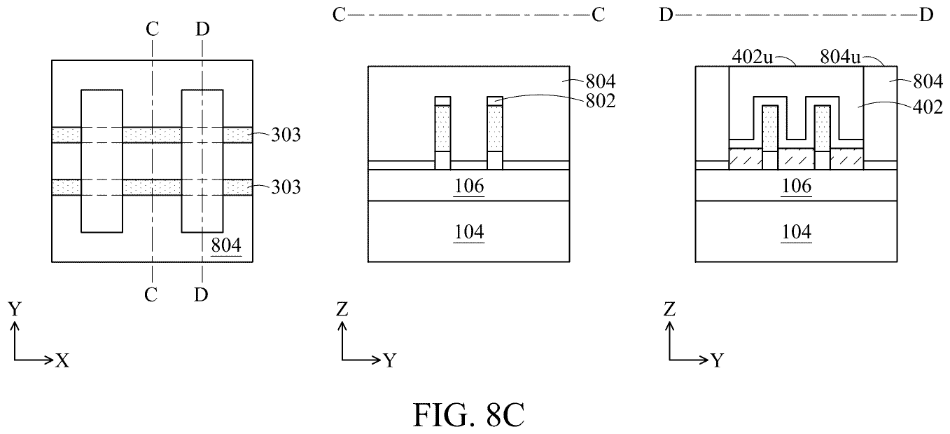

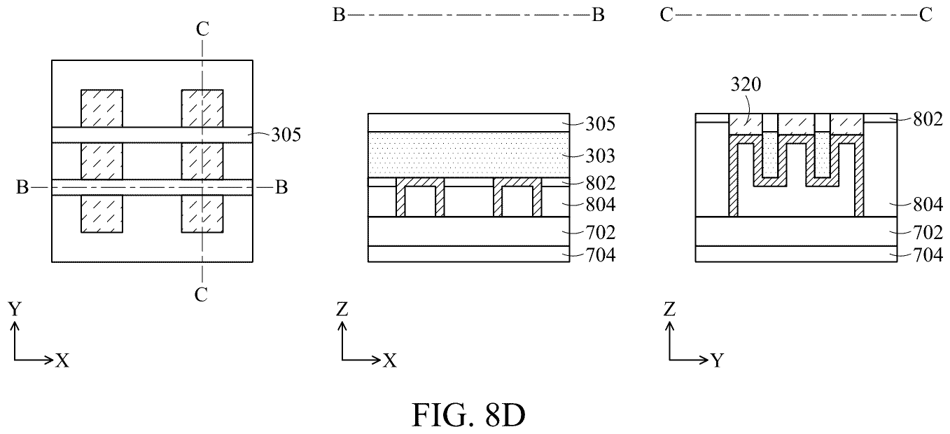

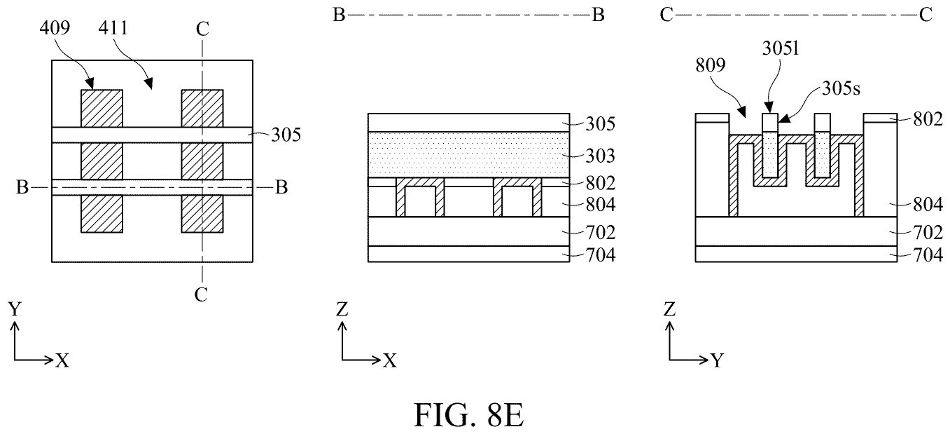

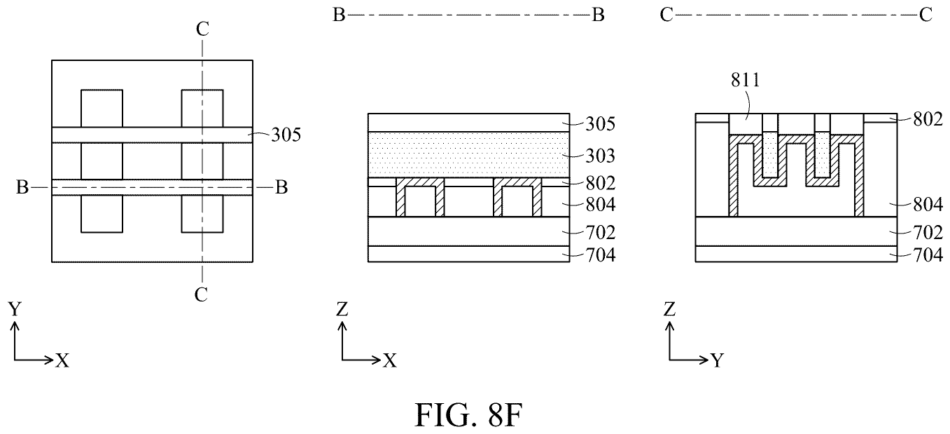

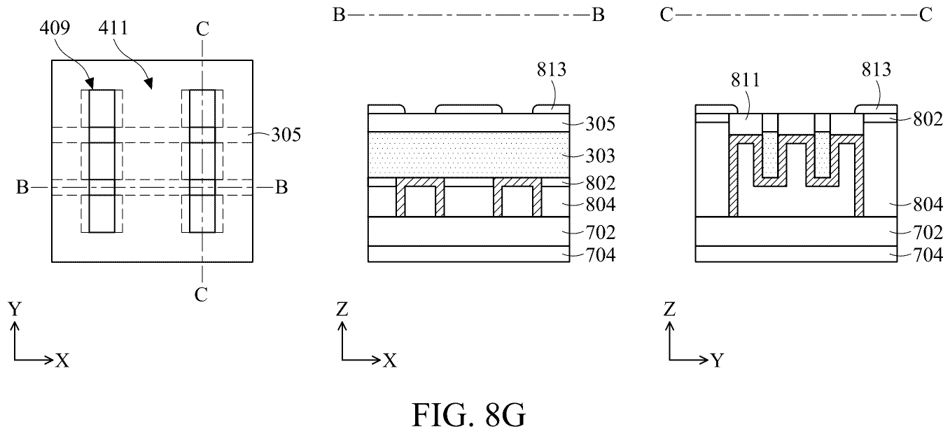

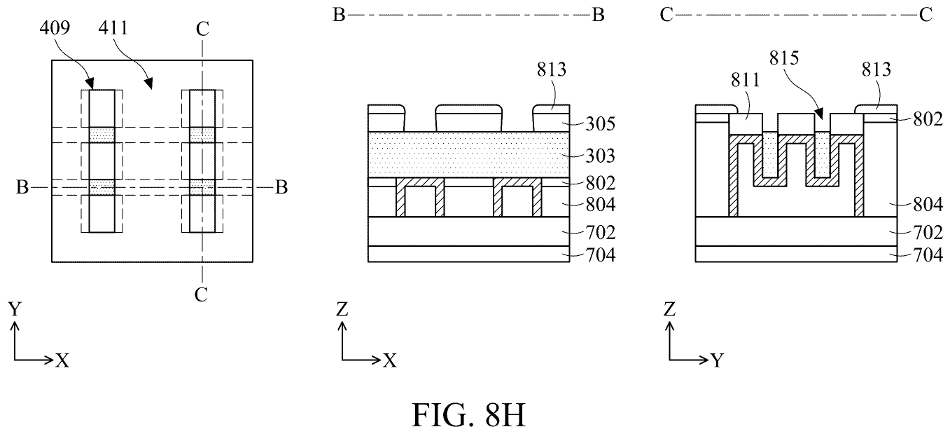

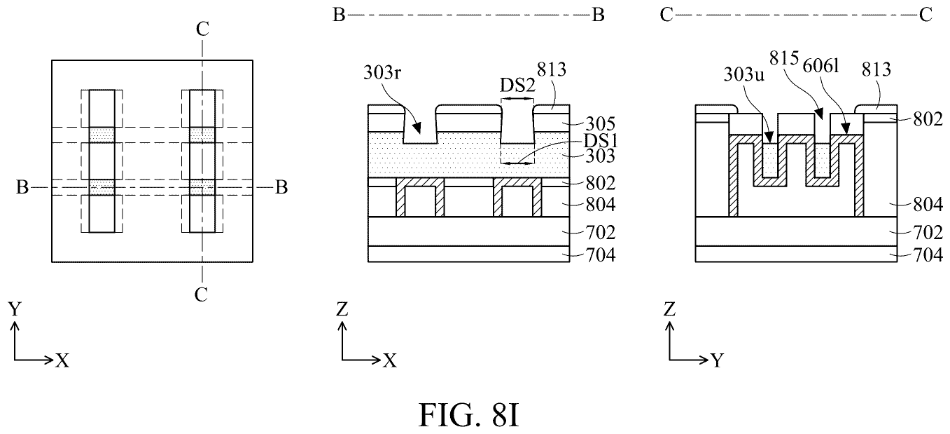

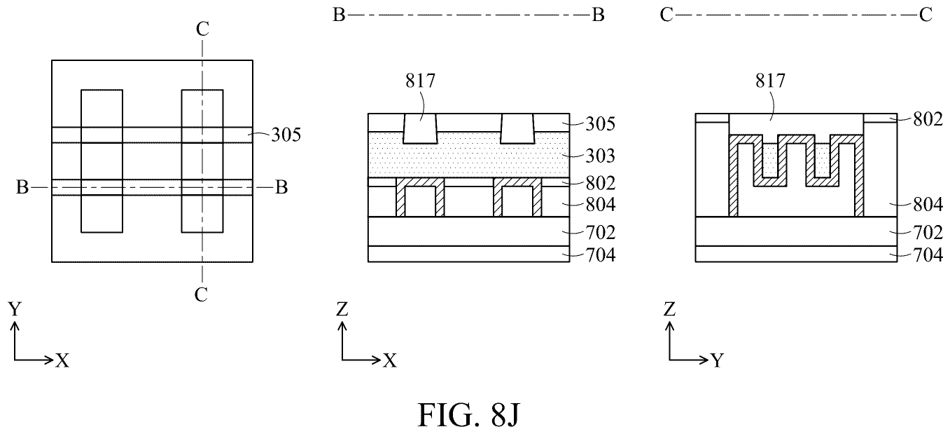

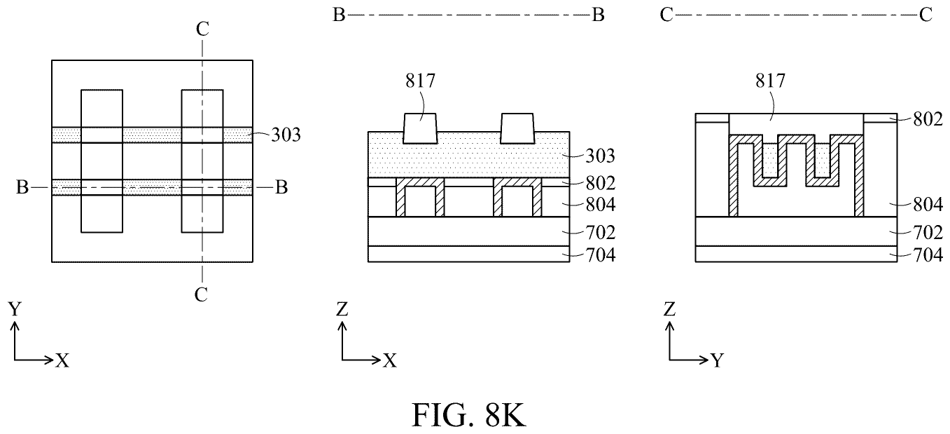

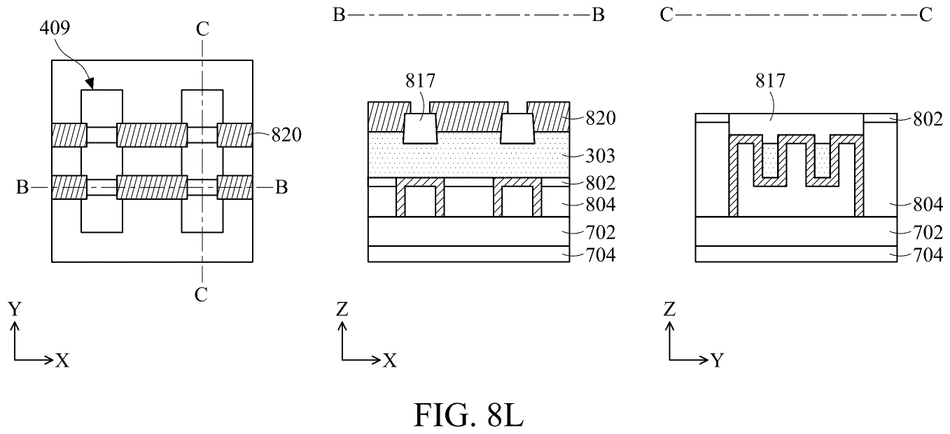

FIGS. 8A-8L are diagrams of another example implementation of forming the semiconductor device 102 described herein. The example implementation of FIGS. 8A-8L may include some similar processes as described in connection with FIGS. 7A-7I, the detailed description of which is omitted for brevity purposes. Further, the operations shown in FIG. 7J 7K and the operations shown in FIGS. 1-6C can also be performed before or after the example implementation of FIG. 8A-8L.

The implementations shown in FIGS. 8A-8L include use of area-selective atomic layer deposition (ASD) technique applied on different materials of adjacent areas of a wafer, e.g., different materials of different or same categories of chemical properties. In some implementations, the ASD techniques are used to generate growth or non-growth surface regions based on different dielectric materials of such surface regions, e.g., SiN versus SiO₂, or materials of different categories of chemical properties, e.g., metal versus dielectric materials. The ASD technique selectively passivates one area of a wafer among adjacent areas and thus generates “growth” and “non-growth” surface areas. A third material will be selectively deposited on a “growth” surface area instead of a “non-growth” surface area. For example, an ASD process is used herein to generate a “non-growth” surface area over the gate 606 and fin structure 302 and a “growth” surface area on the area(s) adjacent to or surrounding the “non-growth” surface area over the gate 606 and fin structure 302.

As shown in FIG. 8A, a dummy gate stack(s) 402 is formed or provided on a first side of a wafer 102.

As shown in FIG. 8B, a first dielectric layer 802 of a first dielectric material, e.g., SiN, is deposited on the surface of the dummy gate stack 402, the semiconductor portion 303 of the fin structure 302, and on the etch stop layer 106. The first dielectric layer 802 is deposited to be thin, e.g., 7 nm thickness. The deposition is controlled so that there is no or reduced amount of sidewall deposition on the dummy gate stack 402 or the fin structure 302. In some implementations, a mild wet etch is performed to remove any material deposited on the sidewall surfaces of the fin structure 302 or the dummy gate stack 402.

As shown in FIG. 8C, a second dielectric layer 804 of a second dielectric material, e.g., SiO2, is deposited adjacent to the dummy gate stack 402. An upper surface 804u of the second dielectric layer 804 is at a same level as the upper surface 402u of the dummy gate structure 402. The upper surface 402u of the dummy gate stack 402 is exposed from the second dielectric layer 804. In some implementations, the second dielectric layer 804 may be initially deposited, e.g., using a CVD procedure or other deposition procedures, to have a thickness of 100-400 nm, e.g., 200 nm. The initially deposited second dielectric layer 804 may be thinned, e.g., using a CMP procedure, to the level of the upper surface 402u of the dummy gate stack 402 and the first dielectric layer 802 is also removed from the top of the dummy gate stack 402 so that the dummy gate stack 402 is exposed from the first dielectric layer 802 and the second dielectric layer 804. The second dielectric layer 804 covers the fin structure 302.

As shown in FIG. 8D, procedures similar to those shown in FIGS. 7A-7C are conducted and as a result, bonding layer 702 and carrier substrate 704 are attached to the front side of the wafer 102 and the substrate 104 and the etch stop layer 106 are removed, which exposes bottoms of the fin structures 302, or specifically the bottoms of the sacrificial portions 305 of the fin structures 302, on the back side of the semiconductor wafer 102. The First dielectric layer 802 is also exposed on the back side of the semiconductor wafer 102. In some implementations, the exposed sacrificial portions 305, the sacrificial layer 320, and the exposed First dielectric layer 802 are on a same level as one another.

As shown in FIG. 8E, the sacrificial layer 320 of, e.g., HTSOC material, is removed using dry etch, which generates an open area 809 corresponding to the gate region 409. After the sacrificial layer 320 has been removed, the lower surface 305l and the sidewall surface 305s of the sacrificial portion 305 of the fin structure 302 are exposed to air in the open area 809 that correspond to the gate region 409, and sidewall surface 303s of the lower part 303l of the semiconductor portion 303 is also exposed to air in the open area 809. Note that before the removal, the sacrificial layer 320 is adjacent to the lower portion 303l of the semiconductor portion 303 of the fin structure 302. In the non-gate area 411, the fin structures 302 including the sacrificial portion 305 and the lower part 303l of the semiconductor portion 303 remain surrounded by the second dielectric layer 804, e.g., SiO2, and the first dielectric layer 802, e.g., of SiN.

As shown in FIG. 8F, a third dielectric layer 811 is formed in the open area 809. In some implementations, the third dielectric layer 811 includes a different dielectric material from that of the first dielectric layer 802. For example, in a case the first dielectric layer 802 is SiN, the third dielectric layer 811 is SiO₂ or other suitable dielectric materials. In the ASD technique applied herein, the area occupied by the first dielectric layer 802 is configured as a “growth” surface area, and the areas occupied by the third dielectric layer 811 or by the sacrificial portion 305 are designated to be non-growth surface areas.

In some implementations, the areas occupied by the third dielectric layer 811 or by the sacrificial portion 305 are passivated to become the non-growth surface areas. There are various approaches to achieve the non-growth surface areas through passivation. For example, area-selective deposition (“ASD”) is used to mask designated areas. In some implementations, the selective deposition of Al₂O₃ on SiN but not on SiO₂ is used to mask designated surface areas. However, it should appreciated that any existing or future developed ASD procedures may be used, and are included in the scope of the disclosure.

As shown in FIG. 8G, in some implementations, a layer 813 of Al₂O₃ or other suitable materials is formed on the “grown” surface area, e.g., the surface area occupied by the first dielectric layer 802 of SiN. An ASD procedure is used to deposit the layer 813. In some implementations, the deposition of the layer 813 is controlled so that the layer 813 is also grown laterally on the sacrificial portion 305 (configured to be non-growth surface area) of the fin structures 302 in the non-gate region 411. The layer 813 is also grown laterally to extend partially over the surface of the third dielectric layer 811 and the sacrificial portion 305 of the fin structures 302 in the gate region 409, although layer 813 does not fully overlap or cover the third dielectric layer 811 or the sacrificial portion 305 of the fin structures 302 in the gate region 409. At least a portion of the sacrificial portion 305 is exposed from the layer 813 in the gate region 409.

As shown in FIG. 8H, the exposed portion of the sacrificial portion 305 is removed from the gate region 409, using the layer 813 as a mask or etch stop layer, thereby generating an opening 815 in the gate region 409 adjacent to the third dielectric layer 811.

As shown in FIG. 8I, the semiconductor portion 303 of the fin structure 302 is recessed through the opening 815 in the gate region 409. In some implementations, the semiconductor portion 303 is recessed such that an upper surface 303u of the semiconductor portion 303 is about 5 nm below the adjacent surface 606l of the gate structure 606. In some implementations, the recessed portion 303r includes a tapered profile such that a dimension DS1 of the upper surface 303u is greater than a dimension DS2 of the opening 815. Note that the lateral overgrowth of the layer 813 makes the opening 815 smaller than the gate region 409 in the x-axis direction, and the tapered profile of the recessed portion 303r can compensate for the impact of the overgrowth of the layer 813.

As shown in FIG. 8J, a dielectric layer 817, e.g., of SiO₂, is deposited to fill the opening 815 and the recessed portion 303r. As such, the dielectric layer 817 also includes a tapered profile within the recessed portion 303r. After that, the layer 813 is at least partially removed to expose the remaining sacrificial portion 305 of the fin structures 302 in the non-gate region 411.

As shown in FIG. 8K, the remaining sacrificial portion 305 is removed from the non-gate region 411 using wet etch or dry etch.

As shown in FIG. 8L, source/drain structure 820 is formed, e.g., as a epitaxy layer, on the semiconductor portion 303 of the fin structure 302 in the non-gate region 411. In some implementations, because the overgrowth of the layer 813 extends into the gate region 409, the source/drain structure 820 also extends slightly into the gate region 409.

As described in greater detail above, some implementations described herein provide a method. The method includes forming a semiconductor fin structure on a first side of a semiconductor device. The method includes forming a gate structure on the first side of the semiconductor device such that the gate structure is located on a top of the semiconductor fin structure. The method includes forming a source/drain structure on a second side of the semiconductor device, vertically opposing the first side, such that the source/drain structure is located on a bottom of the semiconductor fin structure.

As described in greater detail above, some implementations described herein provide a semiconductor device. For example, a semiconductor device includes: a semiconductor protruding structure on a first side of the semiconductor device; a gate structure on the first side of the semiconductor device, the gate structure adjacent to the semiconductor protruding structure and on a first side of the semiconductor protruding structure; and a source or drain structure on a second side of the semiconductor device, opposing the first side, the source or drain structure adjacent to a second side of the semiconductor protruding structure.

Some implementations described herein provide a method. For example, a method includes: forming a semiconductor fin structure on a first side of a semiconductor device; forming a gate structure on the first side of the semiconductor device such that the gate structure is located on a first side of the semiconductor fin structure; recessing a second side of the semiconductor fin structure within a gate region that corresponds to the gate structure to generate a recessed portion in the second side of the semiconductor fin structure, the second side of the semiconductor fin structure vertically opposing the first side of the semiconductor fin structure; forming a dielectric layer in the recessed portion; and forming a source or drain structure on the second side of the semiconductor device and laterally adjacent to dielectric layer.

In another example, a method includes: forming a fin structure on a substrate, the fin structure including a sacrificial portion on the substrate and a semiconductor portion on the sacrificial portion; forming a gate structure adjacent to the fin structure; removing the substrate, which exposes the sacrificial portion of the fin structure; removing a first part of the sacrificial portion that overlaps the gate structure, wherein a second part of the sacrificial portion remains on the semiconductor portion; recessing the semiconductor portion to form a recessed portion, the recessing using the second part of the sacrificial portion as a mask; forming a dielectric layer in the recessed portion; removing the second part of the sacrificial portion to expose the semiconductor portion; and forming a source or drain structure on the exposed semiconductor portion.

The terms “approximately” and “substantially” can indicate a value of a given quantity that varies within 5% of the value (e.g., ±1%, ±2%, ±3%, ±4%, ±5% of the value). These values are merely examples and are not intended to be limiting. It is to be understood that the terms “approximately” and “substantially” can refer to a percentage of the values of a given quantity in light of this disclosure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a semiconductor protruding structure on a first side of the semiconductor device;
a gate structure on the first side of the semiconductor device, the gate structure adjacent to the semiconductor protruding structure and on a first side of the semiconductor protruding structure; and
a source or drain structure on a second side of the semiconductor device, opposing the first side, the source or drain structure adjacent to a second side of the semiconductor protruding structure.

2. The semiconductor device of claim 1, comprising:
a source or drain contact on the source or drain structure.

3. The semiconductor device of claim 1, comprising a dielectric layer partially in the second side of the semiconductor protruding structure, the dielectric layer overlapping the gate structure.

4. The semiconductor device of claim 3, wherein the source or drain structure is on a side of the dielectric layer.

5. The semiconductor device of claim 4, wherein the source or drain structure extends partially on an upper surface of the dielectric layer.

6. The semiconductor device of claim 3, wherein the dielectric layer includes a tapered profile.

7. The semiconductor device of claim 3, wherein the dielectric layer is on the gate structure.

8. The semiconductor device of claim 1, comprising:
a gate contact extending from the second side of the semiconductor device to the gate structure.

9. The semiconductor device of claim 8, wherein the gate contact extends alongside the source or drain structure.

10. A method, comprising:
forming a semiconductor fin structure on a first side of a semiconductor device;
forming a gate structure on the first side of the semiconductor device such that the gate structure is located on a first side of the semiconductor fin structure;
recessing a second side of the semiconductor fin structure within a gate region that corresponds to the gate structure to generate a recessed portion in the second side of the semiconductor fin structure, the second side of the semiconductor fin structure vertically opposing the first side of the semiconductor fin structure;
forming a dielectric layer in the recessed portion; and
forming a source or drain structure on the second side of the semiconductor device and laterally adjacent to dielectric layer.

11. The method of claim 10, wherein the forming the semiconductor fin structure includes forming a semiconductor fin structure including a semiconductor portion and a sacrificial portion, the sacrificial portion includes a material that has etch selectivity with respect to a material of the semiconductor portion, and the sacrificial portion closer to the second side of the semiconductor fin structure than the semiconductor portion.

12. The method of claim 11, wherein the recessing the second side of the semiconductor fin structure within the gate region includes:
removing the sacrificial portion within the gate region; and
recessing the semiconductor portion using a remaining part of the sacrificial portion as a mask.

13. The method of claim 12, comprising forming a sacrificial layer adjacent to the semiconductor fin structure, wherein the forming the gate structure includes:
forming the gate structure on the sacrificial layer, and
patterning the sacrificial layer together with the gate structure.

14. The method of claim 13, wherein the recessing the second side of the semiconductor fin structure within the gate region includes:
removing the sacrificial layer to generate a first open area, and
removing the sacrificial portion within the first open area.

15. The method of claim 13, wherein the forming the sacrificial layer adjacent to the semiconductor fin structure includes forming the sacrificial layer that is laterally adjacent to the semiconductor portion of the semiconductor fin structure.

16. The method of claim 10, wherein the recessing the second side of the semiconductor fin structure within the gate region includes recessing the second side of the semiconductor fin to a level that is below an adjacent surface of the gate structure.

17. The method of claim 12, wherein the forming the source or drain structure on the second side of the semiconductor device includes:
removing the remaining part of the sacrificial portion to expose the semiconductor portion; and
forming the source or drain structure on the exposed semiconductor portion.

18. A method, comprising:
forming a fin structure on a substrate, the fin structure including a sacrificial portion on the substrate and a semiconductor portion on the sacrificial portion;
forming a gate structure adjacent to the fin structure;
removing the substrate, which exposes the sacrificial portion of the fin structure;
removing a first part of the sacrificial portion that overlaps the gate structure, wherein a second part of the sacrificial portion remains on the semiconductor portion;
recessing the semiconductor portion to form a recessed portion, the recessing using the second part of the sacrificial portion as a mask;
forming a dielectric layer in the recessed portion;
removing the second part of the sacrificial portion to expose the semiconductor portion; and
forming a source or drain structure on the exposed semiconductor portion.

19. The method of claim 18, wherein the forming the gate structure comprising:
forming a sacrificial layer adjacent to the fin structure;
forming the gate structure on the sacrificial layer;
patterning the gate structure and the sacrificial layer together; and
wherein the removing the first part of the sacrificial portion that overlaps the gate structure includes:
removing the sacrificial layer to generate a first open area; and
removing the first part of the sacrificial portion in the first open area.

20. The method of claim 19, wherein the removing the first part of the sacrificial portion that overlaps the gate structure includes:
forming a first dielectric layer adjacent to the sacrificial layer;
forming a second dielectric layer different from the first dielectric layer in the first open area after the sacrificial layer has been removed;
passivating a surface area of the second dielectric layer and a surface area of the sacrificial portion; and
selectively forming a layer on the first dielectric layer,
wherein the removing the first part of the sacrificial portion uses the selectively formed layer as a mask.
